(19) United States
(12) Patent Application Publication
(10) Pub. No.: US 2024/0357806 A1
(43) Pub. Date: Oct. 24, 2024

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: JEA-YEON LEE, Suwon-si (KR); YOUNGHO KWON, Suwon-si (KR); SEONKYUNG KIM, Suwon-si (KR); HYUNKOOK LEE, Suwon-si (KR)

(21) Appl. No.: 18/426,868

(22) Filed: Jan. 30, 2024

(30) Foreign Application Priority Data
Apr. 24, 2023 (KR) 10-2023-0053491

(51) Int. Cl. H10B 41/27; H01L 23/522; H01L 23/528; H01L 25/065; H10B 41/35; H10B 43/27; H10B 43/35; H10B 80/00

(52) U.S. Cl. CPC H10B 41/27; H01L 23/5226; H01L 23/5283; H01L 25/0652; H10B 41/35; H10B 43/27; H10B 43/35; H10B 80/00; H01L 2225/06506

(57) ABSTRACT

The present disclosure relates to a semiconductor device and an electronic system including the same, and the semiconductor device according to an embodiment includes: a first substrate; a wire portion disposed on the first substrate and including a wire layer and an insulation layer covering the wire layer; a second substrate disposed on the wire portion; a first gate stacking structure including an interlayer insulating layer and a gate electrode alternately stacked on the second substrate; a second gate stacking structure including an interlayer insulating layer and a gate electrode alternately stacked on the first gate stacking structure; and a channel structure passing through the first gate stacking structure and the second gate stacking structure and connected to the second substrate, wherein the second substrate includes a first material layer and a second material layer disposed on the first material layer, the first material layer includes polysilicon including a first material, the second material layer includes polysilicon including a second material that is different from the first material, and the insulation layer is disposed between the wire layer and the second substrate, and a first side of the first material layer contacts the insulation layer.

### CROSS-REFERENCE TO RELATED APPLICATION

This application claims priority to and the benefit of Korean Patent Application No. 10-2023-0053491 filed on Apr. 24, 2023, in the Korean Intellectual Property Office the entire contents of which is incorporated herein by reference.

### BACKGROUND

### Technical Field

The present disclosure relates to a semiconductor device and an electronic system including the same.

### Description of the Related Art

A semiconductor is a material having electrical properties between a conductor and an insulator, where the material conducts electricity under predetermined conditions. Various semiconductor devices may be manufactured using a semiconductor material, where for example, active and passive devices may be manufactured to form memory devices and logic devices. The memory devices may be classified into volatile memory devices and non-volatile memory devices. In the case of the non-volatile memory devices, information may remain stored in the devices when the power is turned off. Non-volatile memory devices may be used in various electronic devices, such as portable phones, digital cameras, and PCs.

The integration of the non-volatile memory devices may be increased to provide increased storage capacity. The integration of memory devices disposed in two dimensions on a flat surface may be limited. Accordingly, vertical non-volatile memory devices disposed in three dimensions have been proposed.

### SUMMARY

Embodiments of the present disclosure provide a semiconductor device with increased reliability and productivity and an electronic system including the same.

An embodiment of the present disclosure provides a semiconductor device including: a first substrate; a wire portion disposed on the first substrate; a second substrate disposed on the wire portion; a first gate stacking structure on the second substrate; a second gate stacking structure on the first gate stacking structure; and a channel structure passing through the first gate stacking structure and the second gate stacking structure, and electrically connected to the second substrate, wherein the second substrate includes a first material layer and a second material layer disposed on the first material layer, where the first material layer includes polysilicon including a first material, the second material layer includes polysilicon including a second material different from the first material, and an insulation layer is disposed between the wire layer and the second substrate.

The first material layer and the second material layer may have different values of etching selectivity.

The first material layer may include polysilicon doped with carbon, and the second material layer may include n-doped polysilicon.

The wire portion may include a floating electrode disposed between the first substrate and the second substrate, and the second substrate may be electrically connected to the floating electrode.

The floating electrode may be electrically connected to the first substrate.

The floating electrode may electrically float.

The wire portion may further include a plurality of wire layers, and a contact via connecting adjacent pairs of the plurality of wire layers, the insulation layer may cover the plurality of wire layers and the floating electrode, and the floating electrode may include a plurality of layers disposed on a same layer as the plurality of wire layers and the contact via.

A second material layer of the second substrate may be electrically connected to the floating electrode through an opening in the insulation layer and the first material layer.

A first material layer of the second substrate may not be directly connected electrically to the floating electrode.

The channel structure may include a channel layer, and a gate dielectric layer disposed between the channel layer and the first and second gate stacking structures.

The semiconductor device may further include a horizontal conductive layer disposed on the second substrate, wherein the horizontal conductive layer may electrically connects the second substrate and the channel layer.

The channel structure may further include a core insulation layer surrounded by the channel layer, and the gate dielectric layer may include a tunneling layer, a charge storage layer, and a blocking layer sequentially stacked on the channel layer.

Another embodiment of the present disclosure provides a semiconductor device including: a wire portion on a first substrate, wherein the wire portion includes a wire layer and an insulation layer covering the wire layer; a second substrate on the wire portion; a gate stacking structure on the second substrate; and a channel structure passing through the gate stacking structure and electrically connected to the second substrate, wherein the second substrate may include a first material region and a second material region on the first material region, the first material region may include polysilicon doped with carbon, the second material region may include n-doped polysilicon, and the insulation layer may be between the wire layer and the second substrate, and a first side of the first material region may contact the insulation layer.

The first material region and the second material region may have different values of etching selectivity.

The wire portion may include a plurality of wire layers, a contact via electrically connecting the plurality of wire layers, a floating electrode including a plurality of layers on a same layer as the plurality of wire layers and the contact via, and an insulation layer covering the plurality of wire layers and the floating electrode, and the second substrate may be electrically connected to the floating electrode.

A second material region of the second substrate may be electrically connected to the floating electrode through an opening in the insulation layer and the first material region.

The floating electrode may be electrically connected to the first substrate.

Another embodiment of the present disclosure provides an electronic system including: a main substrate; a semiconductor device disposed on the main substrate; and a controller electrically connected to the semiconductor device on the main substrate, wherein the semiconductor device includes a circuit region and a cell region disposed on the circuit region, the circuit region includes a first substrate, a wire layer disposed on the first substrate, and an insulation layer disposed on the wire layer, the cell region includes a second substrate, a first gate stacking structure including an interlayer insulating layer and a gate electrode alternately stacked on the second substrate, a second gate stacking structure including an interlayer insulating layer and a gate electrode alternately stacked on the first gate stacking structure, and a channel structure passing through the first gate stacking structure and the second gate stacking structure and connected to the second substrate, the substrate includes a first material layer and a second material layer disposed on the first material layer, the first material layer includes polysilicon including a first material, the second material layer includes polysilicon including a second material that is different from the first material, and the insulation layer is disposed between the wire layer and the second substrate, and a first side of the first material layer contacts the insulation layer.

The first material layer may include polysilicon doped with carbon, and the second material layer may include n-doped polysilicon.

The wire portion may include a floating electrode between the first substrate and the second substrate, and a second material layer of the second substrate may be electrically connected to the floating electrode.

According to the embodiments, reliability and productivity of the semiconductor device may be increased.

### BRIEF DESCRIPTION OF THE DRAWINGS

FIG. 1 shows a cross-sectional view of a semiconductor device, according to an embodiment.

FIG. 2A and FIG. 2B show cross-sectional views of various examples of a channel structure in a semiconductor device shown in FIG. 1.

FIG. 3 to FIG. 16 sequentially show processing cross-sectional views of a method for manufacturing a semiconductor device, according to an embodiment.

FIG. 17 and FIG. 18 show some of a process for manufacturing a semiconductor device, according to an embodiment.

FIG. 19 and FIG. 20 show some of a process for manufacturing a semiconductor device, according to a reference embodiment.

FIG. 21 shows a cross-sectional view of a semiconductor device, according to an embodiment.

FIG. 22 shows an electronic system including a semiconductor device, according to an embodiment.

FIG. 23 shows a perspective view of an electronic system including a semiconductor device, according to an embodiment.

FIG. 24 and FIG. 25 show cross-sectional views of a semiconductor package, according to an embodiment.

### DETAILED DESCRIPTION

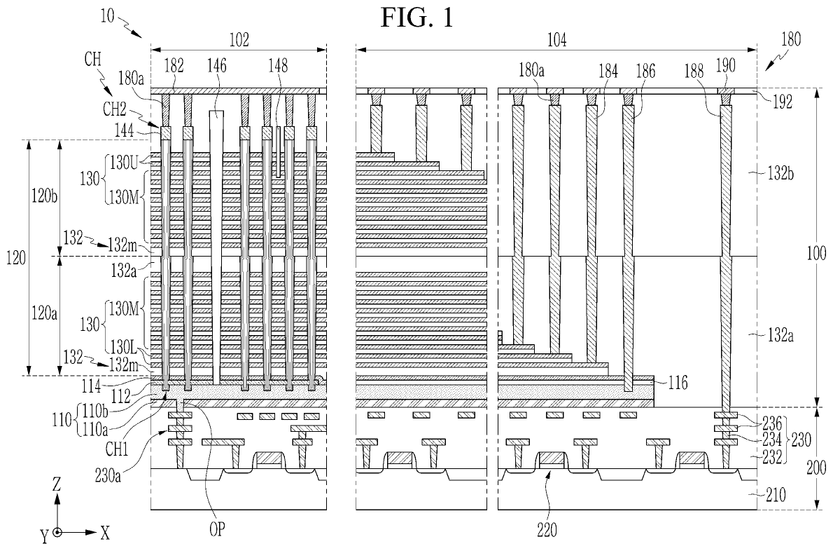

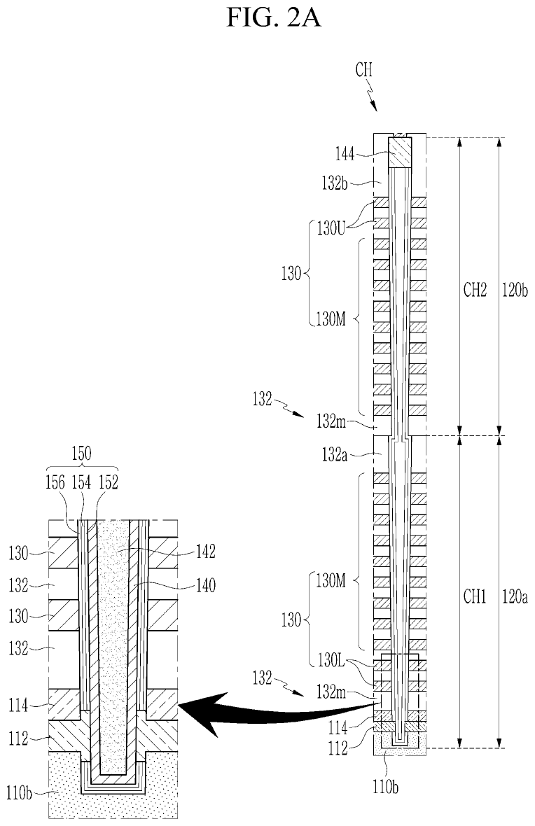

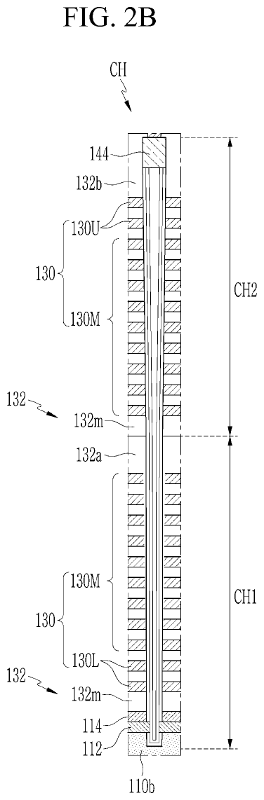

A semiconductor device according to an embodiment will now be described with reference to FIG. 1, FIG. 2A, and FIG. 2B.

FIG. 1 shows a cross-sectional view of a semiconductor device according to an embodiment, and FIG. 2A and FIG. 2B show cross-sectional views of various example of a channel structure in a semiconductor device shown in FIG. 1.

Referring to FIG. 1 and FIG. 2A, the semiconductor device 10 according to an embodiment may include a cell region 100 in which a memory cell structure is formed, and a circuit region 200 in which a peripheral circuit structure, for example, a decoder circuit, a page buffer, or a logic circuit, for controlling an operation of the memory cell structure is formed.

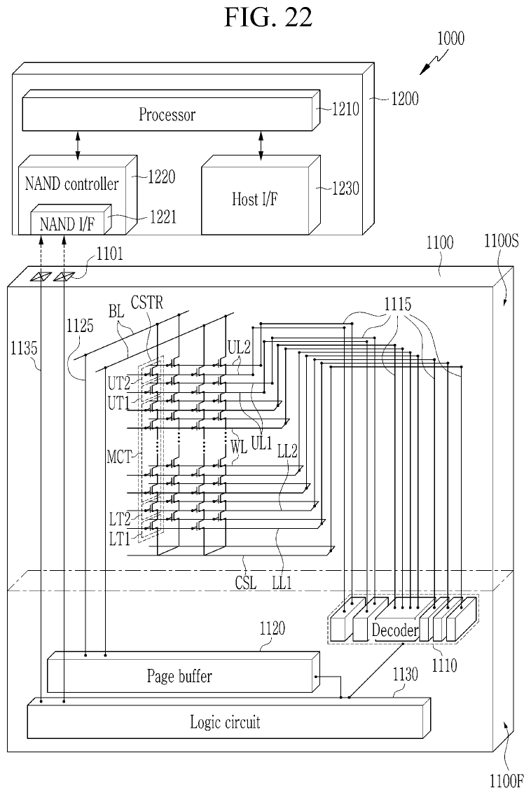

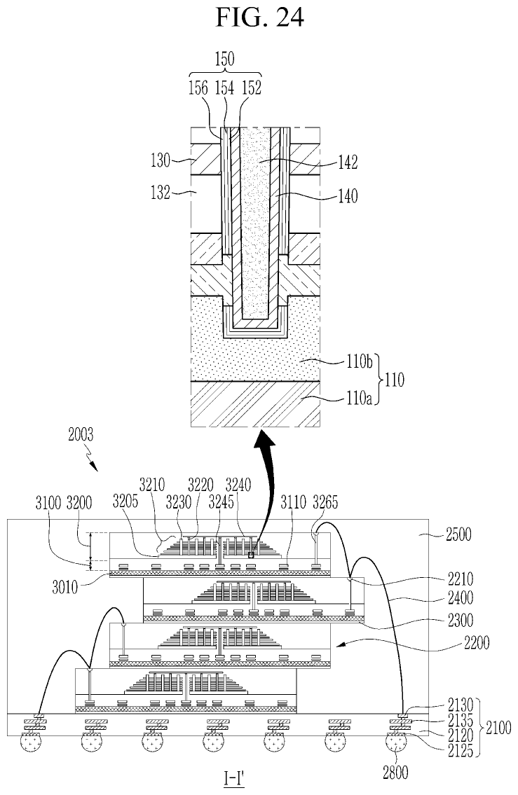

In various embodiments, the circuit region 200 and the cell region 100 may correspond to a first structure 1100F and a second structure 1100S of the semiconductor device 1100 included in the electronic system 1000 shown in FIG. 22. The circuit region 200 and the cell region 100 may also correspond to a first structure 3100 and a second structure 3200 of a semiconductor chip 2200 shown in FIG. 24.

In various embodiments, the circuit region 200 may include a peripheral circuit structure disposed on the first substrate 210. A first wire portion 230 electrically connected to the peripheral circuit structure may be disposed in the circuit region 200, and a second wire portion 180 electrically connected to the memory cell structure may be disposed in the cell region 100, where the second wire portion 180 may be vertically adjacent to the first wire portion 230 and the circuit region 200. The first wire portion 230 may further include a floating electrode 230a, where the floating electrode 230a may be electrically connected to the first substrate 210.

In an embodiment, the cell region 100 may be disposed on the circuit region 200, where the cell region 100 may include a cell array region 102 and a connection region 104. The cell region 100 may include a gate stacking structure 120 and a channel structure CH disposed on the cell array region 102, as a memory cell structure, and an external circuit may be disposed in the connection region 104. A gate stacking structure 120 and a channel structure CH may be disposed on a second substrate 110 in the cell array region 102. In various embodiments, an area corresponding to the circuit region 200 may not be physically separate from the cell region 100, so the area of the semiconductor device 10 may be reduced. However, the embodiment is not limited to this, and a circuit region 200 may be disposed laterally adjacent to the cell region 100 rather than vertically adjacent to the cell region 100. Other various changes are also possible.

In various embodiments, the circuit region 200 may include a first substrate 210, a circuit element 220, and a first wire portion 230 disposed on the first substrate 210.

In various embodiments, the first substrate 210 may be a semiconductor substrate including a semiconductor material. For example, the first substrate 210 may be a semiconductor substrate made of a semiconductor material, or may be a semiconductor substrate generated by forming a semiconductor layer on a base substrate. For example, the first substrate 210 may be made of silicon, epitaxial silicon, germanium, silicon-germanium, a silicon on insulator (SOI), or a germanium on insulator (GOI).

In various embodiments, the circuit element 220 formed on the first substrate 210 may include various types of circuit elements for controlling an operation of the memory cell structure installed in the cell region 100. For example, the circuit element 220 may configure a peripheral circuit structure such as a decoder circuit 1110 of FIG. 22, a page buffer 1120 of FIG. 22, or a logic circuit 1130 of FIG. 22.

The circuit element 220 may, for example, include a transistor, but is not limited thereto. For example, the peripheral circuit element 220 may include active elements such as transistors and passive elements such as capacitors, registers, and/or inductors.

The first wire portion 230 disposed on the first substrate 210 may be electrically connected to the circuit element 220. In an embodiment, the first wire portion 230 may include wire layers 236 spaced apart with a first insulation layer 232 therebetween and connected to form a predetermined electrical path by a contact via 234. The wire layer 236 and the contact via 234 may include various types of conductive materials, and the first insulation layer 232 may include various types of insulating materials.

The cell region 100 may include a cell array region 102 and a connection region 104. A gate stacking structure 120 and a channel structure CH may be disposed on the second substrate 110 in the cell array region 102, where the gate stacking structure 120 may include gate stacking structures 120a and 120b sequentially stacked on the second substrate 110, and the channel structure CH may include channel structures CH1 and CH2 respectively passing through the gate stacking structures 120a and 120b. A structure for connecting the gate stacking structure 120 and/or the channel structure CH disposed in the cell array region 102 to the circuit region 200 or external circuit may be disposed in the connection region 104.

In an embodiment, the second substrate 110 may include a semiconductor material. For example, the second substrate 110 may include polysilicon, which may be doped with impurities. The second substrate 110 may function as a common source line, where the second substrate 110 may function as a source region for supplying currents to the memory cells disposed on the second substrate 110. The second substrate 110 may have a plate shape.

At least part of the first insulation layer 232 may be disposed between the second substrate 110 and the first wire portion 230. A portion of the first insulation layer 232 disposed between the second substrate 110 and the first wire portion 230 may be a single layer or a multilayer. For example, a layer including a silicon nitride and a layer including a silicon oxide may be disposed between the second substrate 110 and the first wire 230. In this instance, the layer including a silicon oxide may be disposed on the layer including a silicon nitride.

In various embodiments, the second substrate 110 may include a first material layer 110a and a second material layer 110b, where the first material layer 110a may be disposed on the first insulation layer 232, and the second material layer 110b may be disposed on the first material layer 110a. In various embodiments, a first material layer 110a may be disposed between the first insulation layer 232 and the second material layer 110b, where the first material layer 110a may be directly on the first insulation layer 232. A first side of the first material layer 110a may contact the first insulation layer 232, where for example, a bottom surface of the first material layer 110a may contact the first insulation layer 232. However, it is not limited to this, and other layers may be further disposed between the first material layer 110a and the first insulation layer 232.

In various embodiments, the first material layer 110a and the second material layer 110b may each include polysilicon. The first material layer 110a and the second material layer 110b may further include different materials, where for example, the first material layer 110a may further include carbon, and the second material layer 110b may further include n-type impurities. For example, the first material layer 110a may include polysilicon including carbon, where the polysilicon can be doped with carbon, and the second material layer 110b may include polysilicon to which n-type impurities have been added as a dopant, where the second material layer 110b can be n-doped polysilicon. The first material layer 110a and the second material layer 110b may represent a first material region and a second material region to which different dopant materials may be added.

In various embodiments, the first wire portion 230 may further include a floating electrode 230a, where the floating electrode 230a may include a plurality of layers disposed on a same layers as the plurality of wire layers 236 and the contact vias 234. However, it is not limited to this, and the floating electrode 230a may be disposed on the same layer as some of the plurality of wire layers 236 and the contact via 234. The floating electrode 230a may include a conductive material, where the floating electrode 230a may be in the first insulation layer 232. [0053] in various embodiments, the floating electrode 230a may be electrically connected to the second substrate 110, where for example, the floating electrode 230a may be electrically connected to the second material layer 110b of the second substrate 110. The first insulation layer 232 and the first material layer 110a of the second substrate 110 may include openings OP. The second material layer 110b may be connected to the floating electrode 230a through the openings OP formed in the first insulation layer 232 and the first material layer 110a, where the second material layer 110b can extend through an opening OP to the floating electrode 230a and be in electrical contact with the floating electrode 230a. The floating electrode 230a may not be directly connected to the first material layer 110a, where the second material layer 110b may separate the first material layer 110a from the floating electrode 230a. The first material layer 110a may be connected to the second material layer 110b, where the first material layer 110a may be indirectly connected to the floating electrode 230a through the second material layer 110b.

In various embodiments, an electrical signal may not be applied to the floating electrode 230a, and the floating electrode 230a may float electrically, where the floating electrode may not have a voltage or electrical signal applied. Where the floating electrode 230a is electrically connected to the second substrate 110, plasma charges stored on the second substrate 110 may be removed in the process of manufacturing a semiconductor device 10 according to an embodiment. For example, the stored charges may be discharged to the first substrate 210 through the floating electrode 230a.

In various embodiments, a gate stacking structure 120 including a cell insulation layer 132 and a gate electrode 130 alternately stacked on a first side (for example, a front side or an upper side) of the second substrate 110, and a channel structure CH passing through the gate stacking structure 120 and extending in a direction traversing the second substrate 110 may be formed in the cell array region 102.

Horizontal conductive layers 112 and 114 may be provided between the second substrate 110 and the gate stacking structure 120 in the cell array region 102, where the horizontal conductive layers 112 and 114 can extend parallel to the surface of the second substrate 110. The horizontal conductive layers 112 and 114 may electrically connect a gap between the channel structure CH and the second substrate 110. For example, the horizontal conductive layers 112 and 114 may include a first horizontal conductive layer 112 disposed on the first side of the second substrate 110, and may further include a second horizontal conductive layer 114 disposed on the first horizontal conductive layer 112, where the first horizontal conductive layer 112 may be disposed between the second substrate 110 and the second horizontal conductive layer 114. The first horizontal conductive layer 112 may not be provided, but the horizontal insulation layer 116 may be provided between the second substrate 110 and the gate stacking structure 120 in a predetermined region of the connection region 104. In the manufacturing process, a portion of the horizontal insulation layer 116 may be replaced with the first horizontal conductive layer 112, whereas another portion of the horizontal insulation layer 116 disposed in the connection region 104 may remain in the connection region 104.

In various embodiments, the first horizontal conductive layer 112 may function as part of the common source line of the semiconductor device 10. For example, the first horizontal conductive layer 112 may function as the common source line together with the second substrate 110. As shown in the enlarged drawing of FIG. 2A, the channel structure CH extends through the horizontal conductive layers 112 and 114 and reaches the second substrate 110, and a gate dielectric layer 150 may be removed from a portion on which the first horizontal conductive layer 112 is disposed, so the first horizontal conductive layer 112 may be directly connected to the channel layer 140 on a circumference of a channel layer 140, where the first horizontal conductive layer 112 may be around the channel layer 140. Accordingly, the first horizontal conductive layer 112 may electrically connect the second substrate 110 and the channel layer 140.

In various embodiments, the first and the second horizontal conductive layers 112 and 114 may include a semiconductor material (e.g., polysilicon), where for example, the first horizontal conductive layer 112 may include polysilicon to which impurities are doped, and the second horizontal conductive layer 114 may include polysilicon to which impurities are doped or may include impurities diffused from the first horizontal conductive layer 112. However, the embodiment is not limited thereto, and the second horizontal conductive layer 114 may include an insulating material. Alternatively, the second horizontal conductive layer 114 may not be provided separately, where the thickness of the first horizontal conductive layer 112 can be increased to fill the space of the second horizontal conductive layer 114.

Referring to FIG. 1, a gate stacking structure 120 in which the cell insulation layer 132 and the gate electrode 130 are alternately stacked may be disposed on the second substrate 110 (e.g., on the first and second horizontal conductive layers 112 and 114 formed on the second substrate 110).

In an embodiment, the gate stacking structure 120 may include gate stacking structures 120a and 120b, where the gate stacking structures 120a and 120b may be sequentially stacked on the second substrate 110. The number of stacked gate electrodes 130 may be increased so the number of memory cells may be increased in a stable structure, where for example, the gate stacking structure 120 may include the first gate stacking structure 120a and the second gate stacking structure 120b, which may simplify the structure while increasing the data storage capacity. However, the embodiment is not limited thereto, and the gate stacking structure 120 may be made of one gate stacking structure, or may include three or more gate stacking structures.

In various embodiments, the gate electrode 130 may include a lower gate electrode 130L, a memory cell gate electrode 130M, and an upper gate electrode 130U sequentially disposed on the second substrate 110 in the gate stacking structure 120. The first channel structure CH1 may passing through the lower gate electrode 130L and the memory cell gate electrode 130M, and the second channel structure CH2 may passing through the memory cell gate electrode 130M and the upper gate electrode 130U. The lower gate electrode 130L may be used as a gate electrode of a ground selecting transistor, the memory cell gate electrode 130M may configure a memory cell, and the upper gate electrode 130U may be used as a gate electrode of a string selecting transistor. The number of memory cell gate electrodes 130M may be determined by data storage capacity of the semiconductor device 10. According to embodiments, one or more lower gate electrodes 130L and upper gate electrodes 130U may be formed, and may have the same or different structures as/from the memory cell gate electrode 130M. In various embodiments, part of the gate electrode 130, for example, the memory cell gate electrodes 130M disposed near the lower gate electrode 130L and the upper gate electrode 130U may be dummy gate electrodes.

In various embodiments, the cell insulation layer 132 may include an interlayer insulating layer 132m disposed beneath a lower portion of the gate electrode 130, where the interlayer insulating layer 132m may be between the lower gate electrode 130L and the second horizontal conductive layer 114. The interlayer insulating layer 132m may be between the two neighboring gate electrodes 130 in the first and second gate stacking structures 120a and 120b, where the upper insulation layers 132a and 132b may be disposed on upper portions of the first and second gate stacking structures 120a and 120b. For example, the upper insulation layers 132a and 132b may include a first upper insulation layer 132a disposed on the upper portion of the first gate stacking structure 120a and a second upper insulation layer 132b disposed on the upper portion of the second gate stacking structure 120b. The first upper insulation layer 132a may be an intermediate insulation layer disposed between the first gate stacking structure 120a and the second gate stacking structure 120b, and the second upper insulation layer 132b may be an uppermost insulation layer disposed on an uppermost portion of the gate stacking structure 120. The second upper insulation layer 132b may be a portion or all of the cell region insulation layer disposed on the upper portion of the cell region 100. In an embodiment, the thicknesses of the different cell insulation layers 132 may not be equal to each other, where for example, the upper insulation layers 132a and 132b may be thicker than the interlayer insulating layer 132m. However, forms or structures of the cell insulation layer 132 are modifiable in many ways depending on embodiments.

For a simple illustration, the drawing in FIG. 2A shows that the cell insulation layer 132 has a border between the first stacking structure 120a and the second stacking structure 120b in the connection region 104. However, the embodiment is not limited to this. A plurality of insulation layers may have various types of stacking structures in the connection region 104, and the embodiment is not limited thereto.

The gate electrode 130 may include various types of conductive materials, where for example, the gate electrode 130 may include a metallic material such as tungsten (W), copper (Cu), or aluminum (Al). For another example, gate electrode 130 may include polysilicon, a metal nitride (e.g., a titanium nitride (TiN), tantalum nitride (TaN), etc.), or combinations thereof. In various embodiments, an insulation layer made of an insulating material may be disposed on an outside of the gate electrode 130, or part of the gate dielectric layer 150 may be disposed thereon. The cell insulation layer 132 may include various types of insulating materials, where for example, the cell insulation layer 132 may include a silicon oxide, a silicon nitride, a silicon oxynitride, a low dielectric constant (low-k) material with a dielectric constant that is lower than that of the silicon oxide, or combinations thereof.

In an embodiment, a channel structure CH may extend in a direction (e.g., a vertical direction that is perpendicular to the surface of the second substrate 110) (a Z-axis direction in the drawing) passing through the gate stacking structure 120 and traversing the second substrate 110.

In various embodiments, the channel structure CH may include a channel layer 140, and a gate dielectric layer 150 disposed on the channel layer 140, where at least a portion of the gate dielectric layer 150 may be between the gate electrode 130 and the channel layer 140. The channel structure CH may further include a core insulation layer 142 disposed inside the channel layer 140, and may further include a channel pad 144 disposed on the channel layer 140 and/or the gate dielectric layer 150 (e.g., see FIG. 2A).

In various embodiments, the channel structures CH may respectively form one memory cell string, and the channel structures CH may form rows and columns and may be spaced apart from each other. For example, the channel structures CH may be disposed in various forms, such as a lattice form or a zigzag form, as viewed in a plan view. The channel structure CH may have a column shape. For example, the channel structure CH may have an inclined side, so that its width becomes narrower as it approaches the second substrate 110 according to an aspect ratio in a cross-sectional view. However, the embodiment is not limited thereto, and the channel structure CH may have various dispositions, structures, and shapes.

In various embodiments, a core insulation layer 142 may be provided in a central region of the channel structure CH, and a channel layer 140 may be formed surrounding sidewalls of the core insulation layer 142. For example, the core insulation layer 142 may have a column shape (e.g., a cylindrical shape or a polygonal column shape), and the channel layer 140 may have a planar shape, such as an annular shape. However, the embodiment is not limited thereto. In various embodiments, the core insulation layer 142 may not be provided and the channel layer 140 may instead have a column shape (e.g., a cylindrical shape or a polygonal column shape).

The channel layer 140 may include a semiconductor material, for example, polysilicon. The core insulation layer 142 may include various types of insulating materials, where for example, the core insulation layer 142 may include a silicon oxide, a silicon nitride, a silicon oxynitride, or combinations thereof. However, materials of the channel layer 140 and the core insulation layer 142 are not limited thereto.

In various embodiments, the gate dielectric layer 150 disposed between the gate electrode 130 and the channel layer 140 may include a tunneling layer 152, a charge storage layer 154, and a blocking layer 156 sequentially stacked on the channel layer 140, where the charge storage layer 154 may be between the tunneling layer 152 and the blocking layer 156 (e.g., see FIG. 2A). The blocking layer 156 may be adjacent to the gate electrode 130.

In this instance, the tunneling layer 152 may allow charges to be tunneled according to a voltage applied to the gate electrode 130, and may include an insulating material through which the charges may be tunneled, where the tunneling layer 152 may include a material such as a silicon oxide or a silicon oxynitride. For example, the tunneling layer 152 may be formed by stacking a layer including a silicon oxide and a layer including a silicon nitride.

The charge storage layer 154 disposed between the tunneling layer 152 and the blocking layer 156 may be used as a data storage region, where for example, the charge storage layer 154 may include a silicon nitride for trapping the charges. When the charge storage layer 154 is made of a silicon nitride, it may provide improved retention compared to polysilicon, which can be advantageous in integration. However, the material of the charge storage layer 154 is not limited thereto.

The blocking layer 156 may be disposed between the charge storage layer 154 and the gate electrode 130. The blocking layer 156 may include an electrically insulating material for preventing an undesirable flow of charges to the gate electrode 130. For example, the blocking layer 156 may include a silicon oxide, a silicon nitride, a silicon oxynitride, a high dielectric constant material, or combinations thereof.

A high dielectric constant material can be a dielectric material having a dielectric constant that is higher than that of the silicon oxide. For example, the high dielectric constant material may include, but not be limited to, an aluminum oxide (Al₂O₃), a tantalum oxide (Ta₂O₃), a titanium oxide (TiO₂), a yttrium oxide (Y₂O₃), a zirconium oxide (ZrO₂), a zirconium silicon oxide (ZrSiₓO_{y}), a hafnium oxide (HfO₂), a hafnium silicon oxide (HfSiₓO_{y}), a lanthanum oxide (La₂O₃), a lanthanum aluminum oxide (LaAlₓO_{y}), a lanthanum hafnium oxide (LaHfₓO_{y}), a hafnium aluminum oxide (HfAlₓO_{y}), a praseodymium oxide (Pr₂O₃), and combinations thereof.

In various embodiments, the channel pad 144 may be disposed on the channel layer 140 and/or the gate dielectric layer 150. The channel pad 144 may cover an upper side of the core insulation layer 142 and be electrically connected to the channel layer 140. Although, the channel pad 144 is shown in FIG. 2A to cover an upper side of the gate dielectric layer 150, the feature is not intended to be limited thereto. For example, the channel pad 144 may not cover the upper side of the gate dielectric layer 150, but instead a lateral side of the channel pad 144 may be surrounded by the gate dielectric layer 150. The lateral side of the channel pad 144 may be in contact with the tunneling layer 152. The channel pad 144 may include a conductive material, for example, impurity-doped polysilicon. However, the material of the channel pad 144 is not limited thereto, and it may be modifiable in many ways.

When the gate stacking structure 120 includes the stacked gate stacking structures 120a and 120b, as described above, the channel structure CH may have channel structures CH1 and CH2 respectively passing through the gate stacking structures 120a and 120b. For example, when the gate stacking structure 120 includes the first gate stacking structure 120a and the second gate stacking structure 120b, the channel structures CH may include a first channel structure CH1 passing through the first gate stacking structure 120a and extending therefrom, and a second channel structure CH2 passing through the second gate stacking structure 120b and extending therefrom (e.g., see FIG. 2A).

The first channel structure CH1 may be physically and electrically connected to the second channel structure CH2. The first channel structure CH1 and the second channel structure CH2 may each have an inclined lateral side such that the width becomes narrower as they approach the second substrate 110 according to an aspect ratio in a cross-sectional view. As shown in FIG. 2A, a bent portion may be provided at a portion where the first channel structure CH1 is connected to the second channel structure CH2 due to a difference in width, where the first channel structure CH1 may be wider than the second channel structure CH2. For another example, as shown in FIG. 2B, the first channel structure CH1 and the second channel structure CH2 may have inclined lateral sides continuously connected with no bent portion. However, the shapes of the first channel structure CH1 and the second channel structure CH2 are not limited thereto, and may be modifiable in many ways.

FIG. 1 illustrates that the gate dielectric layer 150, the channel layer 140, and the core insulation layer 142 of the first channel structure CH1 and the second channel structure CH2 extend with each other to form an integral structure. When forming a first penetration portion for the first channel structure CH1 and a second penetration portion for the second channel structure CH2, the gate dielectric layer 150, the channel layer 140, and the core insulation layer 142 may be formed over the first and second penetration portions to form the above-described structure. However, the embodiment is not limited thereto. For another example, the gate dielectric layers 150, the channel layers 140, and the core insulation layers 142 of first channel structure CH1 and the second channel structure CH2 may be formed separately from each other and may be electrically connected to each other. For example, the gate dielectric layer 150, the channel layer 140, and the core insulation layer 142 may be formed in the first penetration portion when the first penetration portion for the first channel structure CH1 is formed, and the gate dielectric layer 150, the channel layer 140, and the core insulation layer 142 may be formed in the second penetration portion when the second penetration portion for the second channel structure CH2 is formed, where the first penetration portion and the second penetration portion may be formed sequentially. Other various changes are possible.

In an embodiment, the channel pad 144 may be provided on the channel structure CH (e.g., the second channel structure CH2) provided in the gate stacking structure 120 (e.g., the second gate stacking structure 120b), where the channel pad 144 may be provided on an upper portion of the gate stacking structures 120. Alternatively, the channel pad 144 may be respectively provided on the first channel structure CH1 and the second channel structure CH2, where the channel pad 144 of the first channel structure CH1 may be connected to the channel layer 140 of the second channel structure CH2.

In an embodiment, the gate stacking structure 120 may extend in a direction (e.g., a vertical direction, a Z-axis direction in the drawing) crossing the second substrate 110 and may be partitioned into multiple partitions in a plan view by a separation structure 146 penetrating the gate stacking structure 120 (e.g., see FIG. 1).

For example, the separation structure 146 may penetrate the gate electrode 130 and the cell insulation layer 132 and may extend to the second substrate 110. The separation structure 146 may extend into the horizontal conductive layers 112 and 114. The separation structure 146 may be provided in plurality, so that the same may extend in a first direction (e.g., a Y-axis direction in the drawing) and may be spaced apart from each other at predetermined intervals in a second direction (e.g., an X-axis direction in the drawing) traversing the first direction in a plan view. Accordingly, the gate stacking structures 120 may respectively extend in a first direction (e.g., the Y-axis direction in the drawing) and may be spaced apart from each other at predetermined intervals in the second direction (e.g., the X-axis direction in the drawing), where the first direction intersects the second direction. The gate stacking structures 120 partitioned by the separation structure 146 may constitute one memory cell block. However, the embodiment is not limited to this, and a range of the memory cell block is not limited thereto.

In various embodiments, the separation structure 146 may have an inclined lateral side that decreases in width toward the second substrate 110 when seen in a cross-sectional view because of a high aspect ratio. However, the embodiment is not limited to this, and the lateral side of the separation structure 146 may be vertical to the second substrate 110. FIG. 1 illustrates that the separation structure 146 has a continuous inclined lateral side in the first gate stacking structure 120a and the second gate stacking structure 120b and does not have a bent part in a cross-sectional view. However, the embodiment is not limited thereto, and the separation structure 146 may have a bent portion at a boundary between the first gate stacking structure 120a and the second gate stacking structure 120b.

In various embodiments, the separation structure 146 may be filled with various types of electrically insulating materials. For example, the separation structure 146 may include an electrically insulating material such as a silicon oxide, a silicon nitride, or a silicon oxynitride. However, the embodiment is not limited thereto, and the structure, shape, and material of the separation structure 146 may be changeable in many ways.

In various embodiments, an upper separation pattern 148 may be formed on an upper portion of the gate stacking structure 120, where the upper separation pattern 148 may extend only partially through an upper portion of the second gate stacking structure 120b. The upper separation pattern 148 may be provided in plurality, so that they may extend in one direction (the Y-axis direction in the drawing) and may be spaced apart from each other at predetermined intervals in an intersection direction (the X-axis direction in the drawing) traversing the one direction.

In various embodiments, the upper separation pattern 148 may be formed by passing through one or a plurality of gate electrodes 130 including the upper gate electrodes 130U disposed between the separation structures 146. The upper separation pattern 148 may, for example, separate the three gate electrodes 130 from each other in the second direction (e.g., the X-axis direction in the drawing). However, the number of the gate electrodes 130 separated by the upper separation pattern 148 is not limited thereto, and it may be modifiable in many ways, where the upper separation pattern 148 may extend through a fewer or greater number of gate electrodes 130. The upper separation pattern 148 may be filled with an insulating material, where for example, the upper separation pattern 148 may include an insulating material such as a silicon oxide, a silicon nitride, or a silicon oxynitride. However, the embodiment is not limited to this, and the structure, shape, and material of the upper separation pattern 148 may be modifiable in many ways.

In order to electrically connect the gate stacking structure 120 and the channel structure CH provided in the cell array region 102 to the circuit region 200 or an external circuit, a connection region 104 and a second wire portion 180 may be provided.

In various embodiments, the second wire portion 180 may include members for electrically connecting the gate electrode 130, the channel structure CH, the horizontal conductive layers 112 and 114 and/or the second substrate 110 to the circuit region 200 or an external circuit. For example, the second wire portion 180 may include a bit line 182, a gate contact portion 184, a source contact portion 186, a penetration plug 188, contact vias 180a respectively connected to them, and a connecting wire 190 for connecting them.

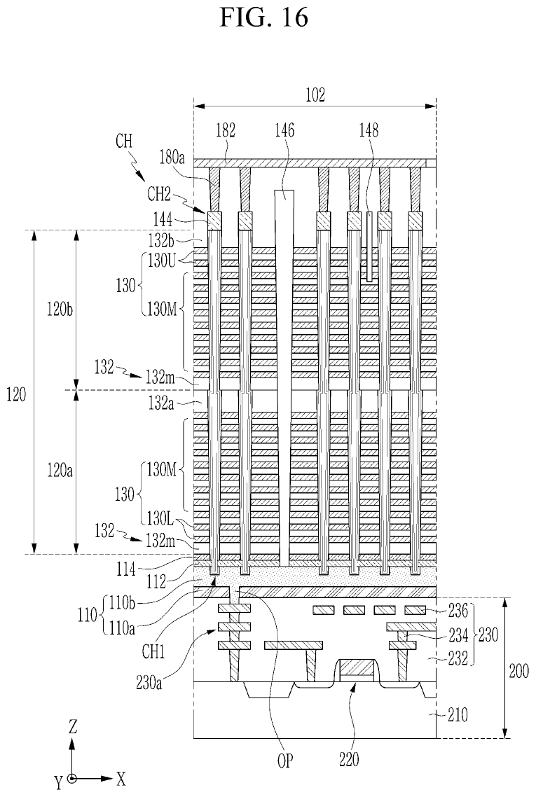

The bit line 182 may be disposed on the cell insulation layer 132 of the gate stacking structure 120 formed in the cell array region 102. The bit line 182 may extend in the second direction (e.g., the X-axis direction in the drawing) traversing the first direction in which the gate electrode 130 extends. The bit line 182 may be electrically connected to the channel structure CH, for example, the channel pad 144 through the contact via 180a, for example, a bit line contact via (e.g., see FIG. 16).

In various embodiments, the connection region 104 may be disposed around the cell array region 102. A portion of the second wire portion 180 may be disposed in the connection region 104. A member for a connection with the gate electrode 130, the horizontal conductive layers 112 and 114 and/or the second substrate 110, and the circuit region 200 may be provided in the connection region 104. In addition, the connection region 104 may include a portion on which an input and output pad and an input and output connecting wire are formed.

In further detail, the gate electrodes 130 may extend in a first direction (e.g., the Y-axis direction in the drawing) in the connection region 104, where the length of the gate electrodes 130 extending in the first direction may be sequentially reduced in the connection region 104, as the gate electrodes 130 become more distant from the second substrate 110. For example, the gate electrodes 130 may be disposed in a stair shape in the connection region 104. In this case, the gate electrode 130 may have a stair shape in one direction or a plurality of directions. In the connection region 104, the gate contact portions 184 may pass through the cell insulation layer 132 and may be electrically connected to the respective gate electrodes 130 extending into the connection region 104, where the gate contact portions 184 may extend to and be in electrical contact with a lower gate electrode 130L.

In the connection region 104, the source contact portion 186 may penetrate the cell insulation layer 132 and may extend into and be electrically connected to the horizontal conductive layers 112 and 114 and/or the second substrate 110, and the penetration plug 188 may penetrate the gate stacking structure 120 or may be disposed outside the gate stacking structure 120 and may be electrically connected to the first wire portion 230 of the circuit region 200.

In various embodiments, the connecting wire 190 may be disposed in the cell array region 102 and/or the connection region 104. The bit line 182, the gate contact portion 184, the source contact portion 186 and/or the penetration plug 188 may be electrically connected to the connecting wire 190. For example, the gate contact portion 184, the source contact portion 186 and/or the penetration plug 188 may be connected to the connecting wire 190 through the contact via 180a.

FIG. 1 shows that the connecting wire 190 is provided as a single layer disposed on the same plane as the bit line 182, and the second insulation layer 192 is disposed on a portion that is not the second wire portion 180. However, this is briefly shown for convenience. Therefore, the connecting wire 190 includes a plurality of wire layers for electrical connection with the bit line 182, the gate contact portion 184, the source contact portion 186 and/or the penetration plug 188, and may further include contact vias.

As described above, the bit line 182, the gate electrode 130, the horizontal conductive layers 112 and 114 and/or the second substrate 110 connected to the channel structure CH may be electrically connected to the circuit element 220 of the circuit region 200 by the second wire portion 180 and the first wire portion 230.

Referring to FIG. 1, the gate contact portion 184, the source contact portion 186, and/or the penetration plug 188 may have an inclined lateral side, so that their widths become narrower as they approach the second substrate 110, according to the aspect ratio. A bent portion may be formed at the boundary between the first gate stacking structure 120a and the second gate stacking structure 120b. However, the embodiment is not limited to this. For example, it is possible for the gate contact portion 184, the source contact portion 186 and/or the penetration plug 188 to not have bent portion at the boundary between the first gate stacking structure 120a and the second gate stacking structure 120b. Other various changes are also possible, such as multiple bent portions.

FIG. 1 illustrates that the gate contact portion 184 passes through the cell insulation layer 132, reaches the gate electrode 130, and is connected to the gate electrode 130 in the connection region 104. However, it is not limited to this, and the gate contact portion 184 may pass through the cell insulation layer 132 and the gate electrode 130, and may extend through the first insulation layer 232 to the first wire portion 230 provided in the circuit region 200. In various embodiments, the gate contact portion 184 may include a pad corresponding to the gate electrode 130 to be connected from among the gate electrodes 130 included in the gate stacking structure 120, and may be insulated from other gate electrodes 130 by an insulating material.

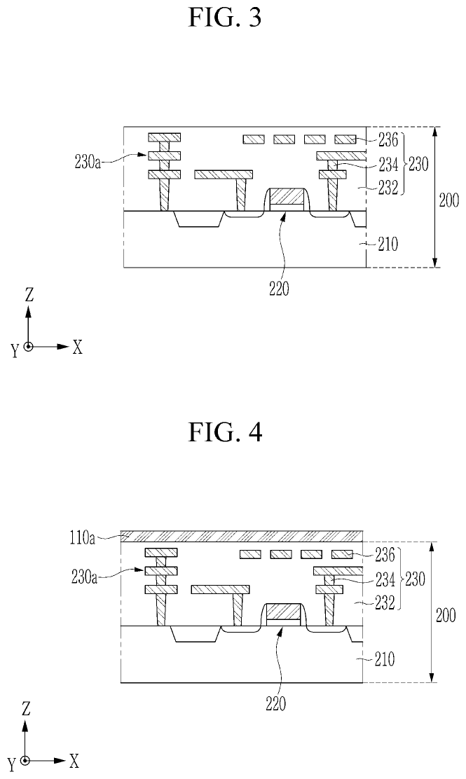

A method for manufacturing a semiconductor device according to an embodiment will now be described with reference to FIG. 3 to FIG. 16.

FIG. 3 to FIG. 16 sequentially show cross-sectional views of a processing method for manufacturing a semiconductor device, according to an embodiment. FIG. 3 to FIG. 16 shows the cell array region 102 for ease of description, and the illustration of the connection region 104 is omitted. A method for manufacturing a cell array region 102 of a semiconductor device 10, according to an embodiment will be mainly described.

As shown in FIG. 3, a peripheral circuit structure may be formed on the first substrate 210. The peripheral circuit structure may include a circuit element 220 and a first wire portion 230. The circuit element 220 including transistors and capacitors may be formed and the first wire portion 230 for connecting the circuit elements 220 may be formed by repeatedly forming an insulating material layer and/or a conducting material layer on the first substrate 210 and patterning the same, and applying a process for doping impurities in a predetermined region of the first substrate 210. The first wire portion 230 may include a first insulation layer 232 for covering the circuit element 220, a plurality of wire layers 236 connected to the circuit element 220, and one or more contact vias 234 connecting the plurality of wire layers 236. The first insulation layer 232 may comprise a plurality of layers, where for example, a first insulation layer 232 for covering the circuit element 220 may be formed, the first insulation layer 232 may be patterned to form an opening, a contact via 234 may be formed to fill the opening, and a wire layer 236 connected to the contact via 234 may be formed. A first insulation layer 232 for covering the wire layer 236 may be formed, and a contact via 234 and a wire layer 236 may be sequentially formed. A process for forming the first insulation layer 232, the contact via 234, and the wire layer 236 may be repeated several times to form several layers. The first wire portion 230 is shown to include three wire layers 236, but is not limited thereto. For example, the first wire portion 230 may include two or one wire layer 236, or may include four or more wire layers 236. A peripheral circuit structure disposed on the first substrate 210 along with the first substrate 210 may be included in the circuit region 200 of the semiconductor device according to an embodiment.

In various embodiments, the first wire portion 230 may further include a floating electrode 230a. The floating electrode 230a may be formed concurrently with the plurality of wire layers 236. The floating electrode 230a may include conductive layers and vias. The conductive layers and the vias of the floating electrode 230a may be respectively formed when the plurality of wire layers 236 and the contact vias 234 are formed. The floating electrode 230a may be physically and electrically connected to the first substrate 210, where for example, the via disposed on a lowermost portion of the floating electrode 230a may be disposed on the first substrate 210. That is, the via disposed on the lowermost portion of the floating electrode 230a may contact the first substrate 210. An upper side of the floating electrode 230a may be covered by the first insulation layer 232. The floating electrode 230a is shown to include three conductive layers and three vias, which is however an example, and the structure of the floating electrode 230a may be modifiable in many ways.

As shown in FIG. 4, a first material layer 110a of the second substrate 110 may be formed on the first insulation layer 232 in the circuit region 200. The first material layer 110a may be formed by using polysilicon. In this instance, the first material layer 110a may include polysilicon including a first material, where for example, the first material layer 110a may include polysilicon including carbon. The first material layer 110a may be formed by using a carbon doping process, an ion implanting process, and/or a gas-plasma doping (GPD) process. The material of the first material layer 110a is not limited thereto, and it may be modifiable in many ways.

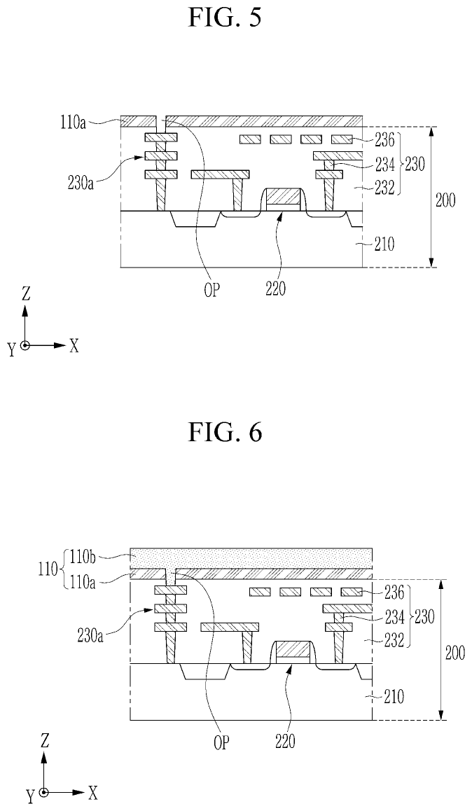

As shown in FIG. 5, the first material layer 110a may be patterned to form an opening OP. For example, the first material layer 110a may be patterned using a photolithography and etching process. The first insulation layer 232 may be patterned in the process for patterning the first material layer 110a. Therefore, the openings OP may be formed in the first material layer 110a and the first insulation layer 232. The openings OP may overlap the floating electrode 230a in a direction (e.g., a vertical direction, a Z-axis direction in the drawing) traversing the second substrate 110. At least a portion of the upper side of the floating electrode 230a may be exposed by the opening OP.

As shown in FIG. 6, a second material layer 110b of the second substrate 110 may be formed on the first material layer 110a including the opening OP. The second material layer 110b may cover the upper side of the first material layer 110a and may fill the opening OP of the first material layer 110a. The second material layer 110b may be formed on the first material layer 110a and may directly contact the first material layer 110a. The second material layer 110b may directly contact the upper side of the floating electrode 230a in the opening OP, where the second material layer 110b may be connected to the floating electrode 230a through the opening OP.

In various embodiments, the second material layer 110b may be made of polysilicon. The second material layer 110b may include polysilicon including a second material that is different from a first material, where for example, the second material layer 110b may include polysilicon to which n-type impurities are doped. However, the material of the second material layer 110b is not limited thereto, and it may be modifiable in many ways, for example, p-type impurities may be added. The first material layer 110a and the second material layer 110b may include polysilicon and may further include different materials. Hence, the first material layer 110a and the second material layer 110b may have different etching rates. When an etching processing is performed by using a predetermined etchant, the second material layer 110b may have higher etching selectivity than the first material layer 110a, such that when the second material layer 110b is etched and the first material layer 110a disposed below the second material layer 110b is exposed, the first material layer 110a may remain substantially unetched.

The first material layer 110a and the second material layer 110b stacked in the circuit region 200 may form the second substrate 110. Shapes, connections, and material of the layers forming the second substrate 110 are not limited thereto, and they may be modifiable in many ways.

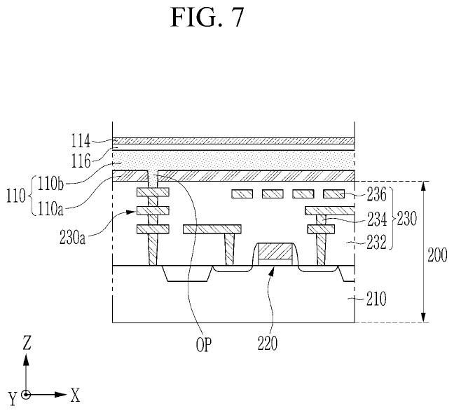

As shown in FIG. 7, a horizontal insulation layer 116 and a second horizontal conductive layer 114 may be formed on the second substrate 110.

In various embodiments, a horizontal insulation layer 116 may be formed on the second substrate 110 using an insulating material, where the horizontal insulation layer 116 may be a single layer or a multilayer. For example, the silicon oxide, the silicon nitride, and the silicon oxide may be sequentially stacked to form a horizontal insulation layer 116. The horizontal insulation layer 116 may have a structure in which a layer of a silicon nitride is disposed between layers of a silicon oxide. At least part of the horizontal insulation layer 116 may be replaced with a first horizontal conductive layer 112 of FIG. 1 in a subsequent process. The horizontal insulation layer 116 may include a portion on which the first horizontal conductive layer 112 of FIG. 1 will be formed.

A second horizontal conductive layer 114 may be formed on the horizontal insulation layer 116. The second horizontal conductive layer 114 may be formed using a semiconductor material (e.g., polysilicon), where for example, the second horizontal conductive layer 114 may include polysilicon to which impurities are doped.

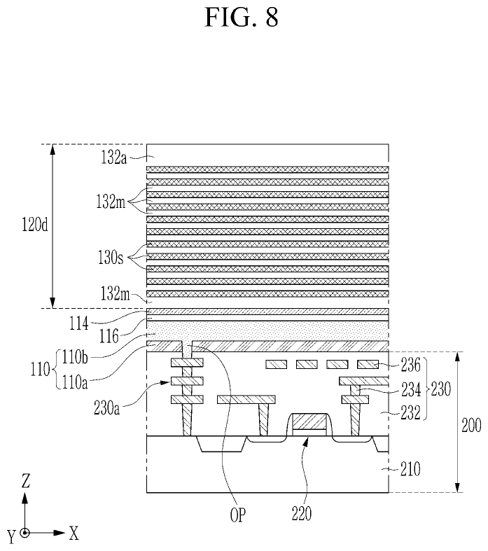

As shown in FIG. 8, interlayer insulating layers 132m and sacrificial insulation layers 130s may be alternately stacked on the second horizontal conductive layer 114 to form a first stacking structure body 120d that is a lower structure body. When the interlayer insulating layer 132m and the sacrificial insulation layer 130s are alternately stacked, a first upper insulation layer 132a may be formed on the uppermost portion and a interlayer insulating layer 132m may be formed on the second horizontal conductive layer 114. The sacrificial insulation layer 130s may be made of a material that is different from the material of the interlayer insulating layer 132m, where the sacrificial insulation layer 130s may be selectively removed. The interlayer insulating layer 132m may include a silicon oxide, a silicon nitride, a silicon oxynitride, and/or a low dielectric constant (low-k) material, and the sacrificial insulation layer 130s may include at least one of silicon, a silicon oxide, a silicon carbide, and a silicon nitride, and may be made of a material that is different from the material of the interlayer insulating layer 132m. For example, the interlayer insulating layer 132m may include a silicon oxide, and the sacrificial insulation layer 130s may include a silicon nitride. At least a portion of the sacrificial insulation layer 130s may be replaced with a gate electrode 130 of FIG. 1 in a subsequent process. That is, the sacrificial insulation layer 130s may correspond to a portion on which the gate electrode 130 of FIG. 1 will be formed.

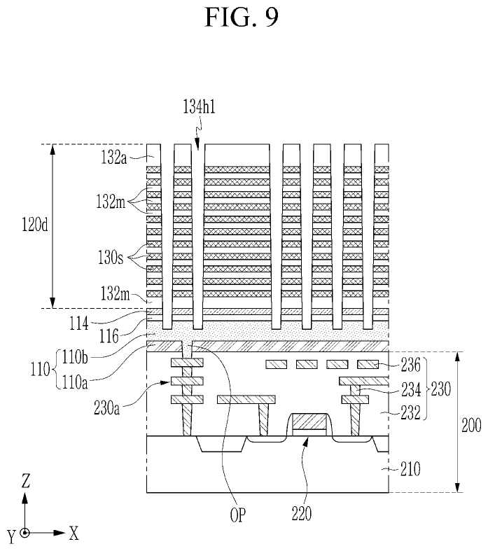

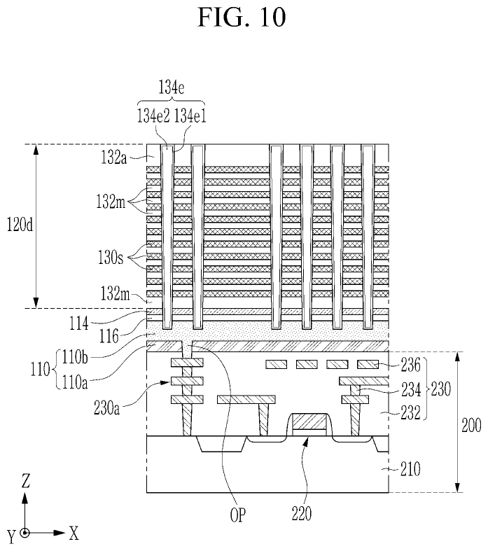

As shown in FIG. 9, the first stacking structure body 120d is patterned to form a first channel hole 134h1. The first stacking structure body 120d may be penetrated by the first channel hole 134H1, where the first channel hole 134H1 may extend to the horizontal insulation layer 116. The second horizontal conductive layer 114, the horizontal insulation layer 116, and the second substrate 110 may be patterned in the process for patterning the first stacking structure body 120d. Therefore, the first channel hole 134H1 having a substantially equivalent planar shape may be formed on the second substrate 110, the horizontal insulation layer 116, the second horizontal conductive layer 114, and the first stacking structure body 120d. The second horizontal conductive layer 114 and the horizontal insulation layer 116 may be penetrated by the first channel hole 134H1, and the second substrate 110 may not be penetrated. A depth of the first channel hole 134H1 formed in the second substrate 110 may be less than a thickness of the second substrate 110. The first channel hole 134H1 may not be formed in the first material layer 110a of the second substrate 110. The first channel hole 134H1 may be formed into the second material layer 110b of the second substrate 110 without extending to the first material layer 110a, where a depth of the first channel hole 134H1 formed in the second material layer 110b of the second substrate 110 may be less than a thickness of the second material layer 110b.

In various embodiments, the first channel holes 134H1 penetrating the first stacking structure body 120d may be spaced apart from each other in rows and columns, as viewed in a plan view. For example, the first channel holes 134H1 may be disposed in various shapes such as a lattice form or a zigzag form in a plan view. The first channel hole 134H1 may have an inclined interior wall surface, so that the width narrows as it approaches the second substrate 110 according to the aspect ratio in a cross-sectional view.

As shown in FIG. 10, a channel sacrificial layer 134e may be formed in the first channel hole 134h1, where the channel sacrificial layer 134e may fill the first channel hole 134h1. The channel sacrificial layer 134e may be a single layer or a multilayer. For example, the channel sacrificial layer 134e may include a first channel sacrificial layer 134e1 and a second channel sacrificial layer 134e2. The first channel sacrificial layer 134e1 may be surrounded by the second channel sacrificial layer 134e2, where the second channel sacrificial layer 134e2 may surround a bottom side, a lateral side, and an upper side of the first channel sacrificial layer 134e1. The first channel sacrificial layer 134e1 and the second channel sacrificial layer 134e2 may include different materials. For example, the first channel sacrificial layer 134e1 may include polysilicon, and the second channel sacrificial layer 134e2 may include a silicon nitride. However, this is an example, and the materials of the first channel sacrificial layer 134e1 and the second channel sacrificial layer 134e2 may not be limited thereto and may be modifiable in many ways.

To cover the bottom side and the sidewall of the first channel hole 134h1, the second channel sacrificial layer 134e2 may be conformally formed. The first channel sacrificial layer 134e1 may be formed to fill the first channel hole 134h1 in the second channel sacrificial layer 134e2. An additional second channel sacrificial layer 134e2 may be formed to cover the upper side of the first channel sacrificial layer 134e1. Hence, the channel sacrificial layer 134e including the first channel sacrificial layer 134e1 and the second channel sacrificial layer 134e2 surrounding the same may be formed.

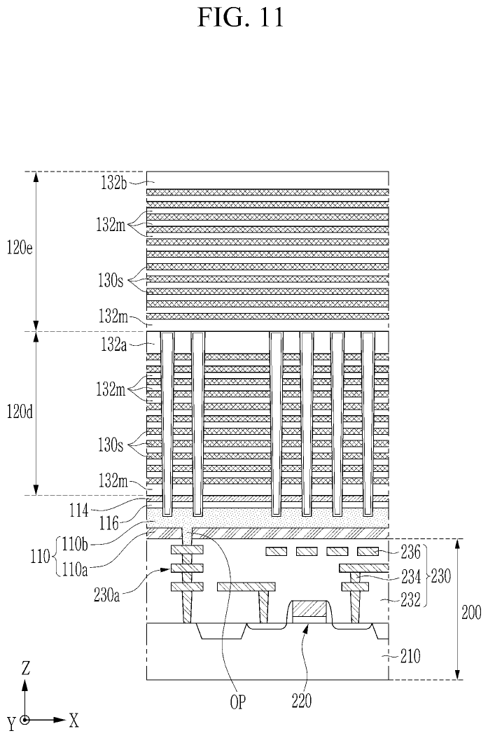

As shown in FIG. 11, interlayer insulating layers 132m and sacrificial insulation layers 130s may be alternately stacked on the first stacking structure body 120d and the channel sacrificial layer 134e to form a second stacking structure body 120e that is an upper structure body. The interlayer insulating layer 132m and the sacrificial insulation layers 130s are alternately stacked, and a second upper insulation layer 132b may then be formed on the uppermost portion. The interlayer insulating layer 132m may be formed on the upper insulation layer 132a of the first stacking structure body 120d. A method for manufacturing the sacrificial insulation layer 130s, the interlayer insulating layer 132m, and the second upper insulation layer 132b of the second stacking structure body 120e may correspond to the process of the first stacking structure body 120d.

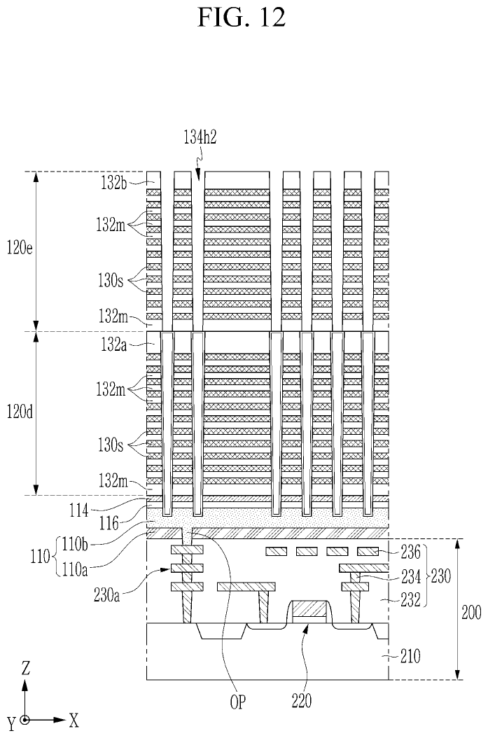

As shown in FIG. 12, the second stacking structure body 120e is patterned to form a second channel hole 134h2. The second stacking structure body 120e may be penetrated by the second channel hole 134h2. The second channel hole 134h2 may be aligned with the first channel hole 134h1 and channel sacrificial layer 134e.

In various embodiments, a plurality of second channel holes 134h2 passing through the second stacking structure body 120e may be formed. The second channel holes 134h2 may be disposed to be spaced from each other in rows and columns in a plan view, where for example, the second channel holes 134h2 may be disposed in various shapes such as a lattice form and a zigzag form in a plan view. The second channel hole 134h2 may have an inclined interior wall surface so that the width narrows as it approaches the second substrate 110 according to the aspect ratio in a cross-sectional view.

In various embodiments, the number of the second channel holes 134h2 may be substantially equivalent to the number of the first channel holes 134h1. The respective second channel holes 134h2 may overlap the first channel holes 134h1. The second channel hole 134h2 may have a shape in which the width gradually decreases when approaching the lower portion from the upper portion. The first channel hole 134h1 may have a shape in which the width gradually decreases when approaching the lower portion from the upper portion. The width of the upper portion of the first channel hole 134h1 may be greater than the width of the lower portion of the second channel hole 134h2, where for example, the width of the upper portion of the first channel hole 134h1 may correspond to the width of the upper portion of the second channel hole 134h2. The widths of the first channel hole 134h1 and the second channel hole 134h2 overlapping each other may be gradually reduced from the uppermost portion, may be increased, and may then be gradually reduced.

When the second channel hole 134h2 is formed, at least part of the channel sacrificial layer 134e may be exposed. For example, a portion of the upper side of the channel sacrificial layer 134e may be exposed by the second channel hole 134h2, where the first channel sacrificial layer 134e1 may be exposed. In an embodiment, the second channel sacrificial layer 134e2 covering the upper side of the first channel sacrificial layer 134e1 may be exposed.

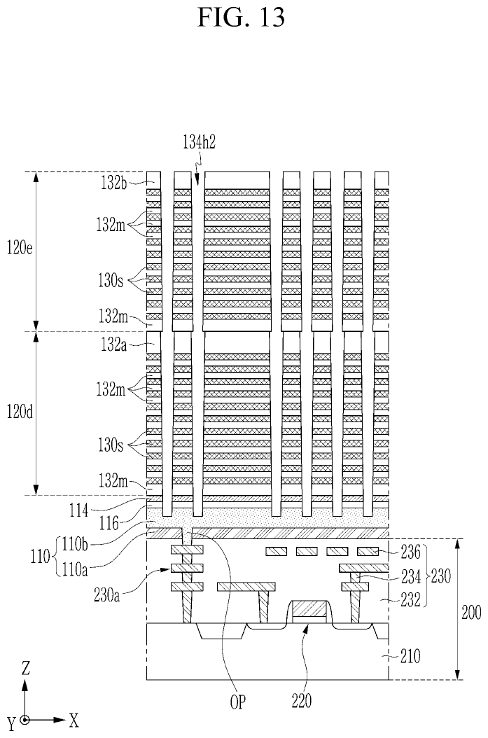

As shown in FIG. 13, the channel sacrificial layer 134e may be removed. A portion of the second channel sacrificial layer 134e2 covering the upper side of the first channel sacrificial layer 134e1 may be etched and removed. Here, the portion of the second channel sacrificial layer 134e2 covering the lateral side and the bottom surface of the first channel sacrificial layer 134e1 may not be removed but may remain on the sidewalls of the first channel hole 134h1. As the second channel sacrificial layer 134e2 is removed, the upper side of the first channel sacrificial layer 134e1 may be exposed. The first channel sacrificial layer 134e1 may be etched and removed.

In various embodiments, the second horizontal conductive layer 114 contacting the channel sacrificial layer 134e and the second material layer 110b of the second substrate 110 may include the same material as the first channel sacrificial layer 134e1, where for example, the second horizontal conductive layer 114, the second material layer 110b, and the first channel sacrificial layer 134e1 may include polysilicon. The second channel sacrificial layer 134e2 may be disposed between the second horizontal conductive layer 114 and the first channel sacrificial layer 134e1, and the second channel sacrificial layer 134e2 may be disposed between the second material layer 110b and the first channel sacrificial layer 134e1. In the process for removing the first channel sacrificial layer 134e1, the second channel sacrificial layer 134e2 disposed between the second horizontal conductive layer 114 and the first channel sacrificial layer 134e1 and between the second material layer 110b and the first channel sacrificial layer 134e1 may not be removed but may remain. Therefore, in the process for removing the first channel sacrificial layer 134e1, the second horizontal conductive layer 114 and the second material layer 110b may not be damaged but may remain.

In various embodiments, a portion of the remaining second channel sacrificial layer 134e2 may be etched and removed. Where the channel sacrificial layer 134e is totally removed, the internal walls of the first stacking structure body 120d and the second stacking structure body 120e penetrated by the first channel hole 134h1 and the second channel hole 134h2 may be exposed to the outside.

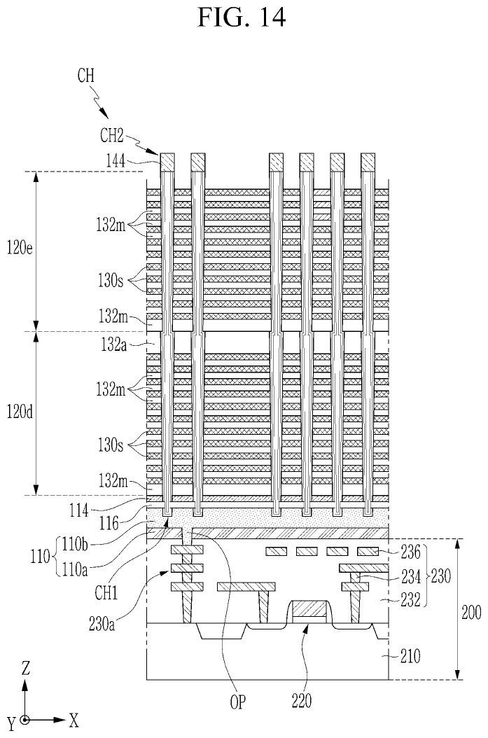

As shown in FIG. 14, a channel structure CH, including the second channel structure CH2 and the first channel structure CH1, may be formed in the first channel hole 134h1 and the second channel hole 134h2. As the channel sacrificial layer 134e is removed, a space formed by the first channel hole 134h1 and the second channel hole 134h2 is generated, where the channel structure CH may be formed to fill the space. The gate dielectric layer 150 of FIG. 2A, the channel layer 140 of FIG. 2A, and the core insulation layer 142 may be sequentially stacked in the first channel hole 134h1 and the second channel hole 134h2, and the channel pad 144 is formed on the channel layer 140 of FIG. 2A, thereby forming the channel structure CH. When forming the gate dielectric layer 150 of FIG. 2A, the gate dielectric layer 150 including multiple layers may be formed by sequentially stacking the blocking layer 156, the charge storage layer 154, and the tunneling layer 152.

The gate dielectric layer 150 of FIG. 2A and the channel layer 140 of FIG. 2A may be formed to have conformal shapes in the first channel hole 134h1 and the second channel hole 134h2, where the gate dielectric layer 150 and the channel layer 140 may be formed to cover internal walls and bottom sides of the first channel hole 134h1 and the second channel hole 134h2. The gate dielectric layer 150 and the channel layer 140 may have inclined lateral sides along the inclined internal walls of the first channel hole 134h1 and the second channel hole 134h2. The first channel hole 134h1 and the second channel hole 134h2 may not be completely filled by the gate dielectric layer 150 and the channel layer 140. Portions of the first channel hole 134h1 and the second channel hole 134h2 that are not filled by the gate dielectric layer 150 and the channel layer 140 may be filled by the core insulation layer 142 of FIG. 2A.

In various embodiments, the channel pad 144 may be formed on the gate dielectric layer 150 of FIG. 2A, the channel layer 140 of FIG. 2A, and the core insulation layer 142 of FIG. 2A. The channel pad 144 may cover the gate dielectric layer 150 of FIG. 2A, the channel layer 140 of FIG. 2A, and the core insulation layer 142 of FIG. 2A. However, they are not limited to this, and the channel pad 144 may cover the upper sides of the channel layer 140 of FIG. 2A and the core insulation layer 142 of FIG. 2A, and may not cover the upper side of the gate dielectric layer 150 of FIG. 2A. In this instance, the gate dielectric layer 150 of FIG. 2A may surround the lateral side of the channel pad 144.

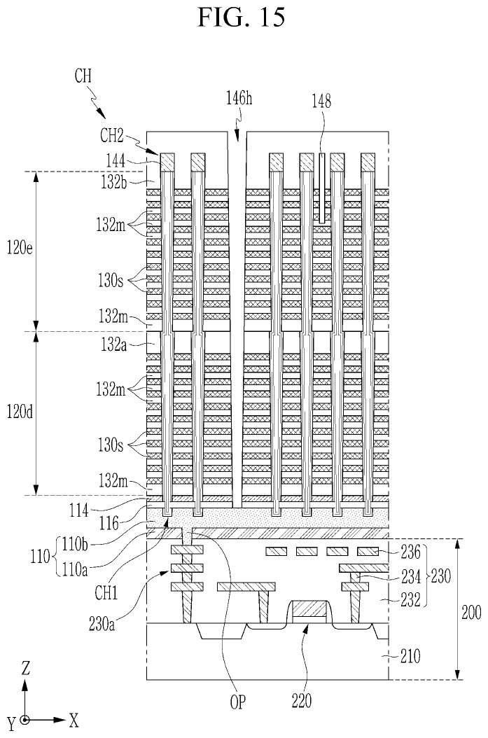

As shown in FIG. 15, the upper separation pattern 148 may be formed on the second stacking structure body 120e. The second stacking structure body 120e may be patterned to form an opening, and the insulating material may be deposited in the opening to form the upper separation pattern 148, which may fill the opening. In this instance, a process for planarizing the upper side of the second stacking structure body 120e and the upper side of the upper separation pattern 148 may be performed, and the insulating material disposed on the second stacking structure body 120e may be removed.

In various embodiments, the upper separation pattern 148 may pass through some of the interlayer insulating layers 132m and the sacrificial insulation layers 130s configuring the second stacking structure body 120e. For example, the upper separation pattern 148 may pass through the second upper insulation layer 132b, the three interlayer insulating layers 132m, and the three sacrificial insulation layers 130s. However, the number of the insulation layers penetrated by the upper separation pattern 148 is not limited thereto, it may be greater or less than the above-noted number. The upper separation pattern 148 may extend in one direction (e.g., the Y-axis direction in the drawing), and the plurality of upper separation patterns 148 may be disposed to be spaced from each other in the other direction (e.g., the X-axis direction in the drawing) traversing the one direction. A predetermined layer of the second stacking structure body 120e disposed on respective sides of the upper separation pattern 148 may be separated by the upper separation pattern 148. Separation openings 146h may be formed in the first stacking structure body 120d and the second stacking structure body 120e. A mask pattern may be formed on the second stacking structure body 120e, the second stacking structure body 120e and the first stacking structure body 120d may be etched, so the separation opening 146h may be formed passing through the first stacking structure body 120d and the second stacking structure body 120e. Lateral sides of respective layers configuring the first stacking structure body 120d and the second stacking structure body 120e may be exposed by the separation opening 146h.

In various embodiments, the separation opening 146h may pass through all layers forming the first stacking structure body 120d and all layers forming the second stacking structure body 120e. The separation opening 146h may pass through the second horizontal conductive layer 114 and the horizontal insulation layer 116. The separation opening 146h may extend in one direction (the Y-axis direction in the drawing), and a plurality of separation openings 146h may be disposed to be spaced from each other in the other direction (the X-axis direction in the drawing) traversing the one direction. The second stacking structure body 120e disposed on respective sides of the separation opening 146h may be separated by the separation opening 146h.

As shown in FIG. 16, the horizontal insulation layer 116 may be removed, and the first horizontal conductive layer 112 may be formed in the space created by removal of the horizontal insulation layer 116. The first horizontal conductive layer 112 may be disposed between the second substrate 110 and the second horizontal conductive layer 114, where the bottom surface of the first horizontal conductive layer 112 may contact the second material layer 110b of the second substrate 110, and the upper side of the first horizontal conductive layer 112 may contact the second horizontal conductive layer 114. The first horizontal conductive layer 112 may include polysilicon to which impurities are doped. The first horizontal conductive layer 112 may function as a common source line together with the second substrate 110 and the second horizontal conductive layer 114.

In various embodiments, the sacrificial insulation layer 130s is removed, and the gate electrode 130 may be formed in the space created when the sacrificial insulation layer 130s is removed. The sacrificial insulation layer 130s may be removed by using an etching process, and the gate electrode 130 may be formed by depositing a metallic material such as tungsten (W), copper (Cu), or aluminum (Al). The gate electrode 130 may include a lower gate electrode 130L, a memory cell gate electrode 130M, and an upper gate electrode 130U sequentially disposed on the second substrate 110. The lower gate electrode 130L may be used as a gate electrode of the ground selecting transistor, the memory cell gate electrode 130M may configure a memory cell, and the upper gate electrode 130U may be used as a gate electrode of the string selecting transistor.

A contact via 180a connected to the channel pad 144 may be formed, and a bit line 182 connected to the contact via 180a may be formed, where the contact via 180a may be electrically connected to the channel pad 144 and the bit line 182. The bit line 182 may extend in the first direction (e.g., the X-axis direction in the drawing) traversing the second direction (e.g., the Y-axis direction in the drawing) in which the gate electrode 130 extends. The bit line 182 may be electrically connect to the channel structure CH, for example, the channel pad 144 through the contact via 180a, for example, the bit line contact via.

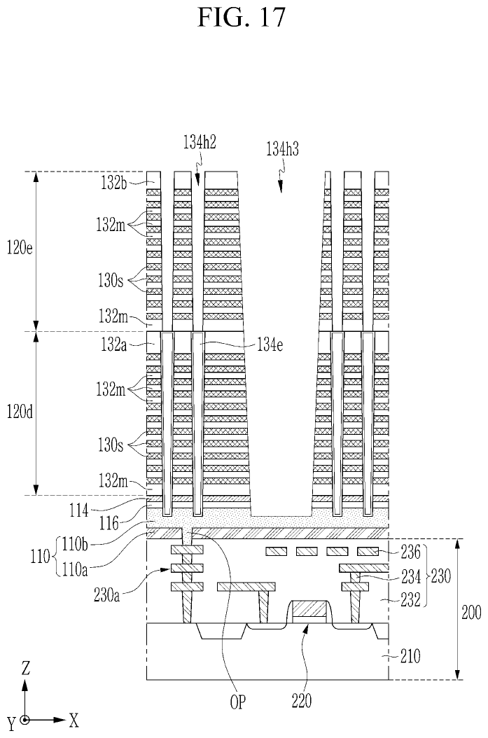

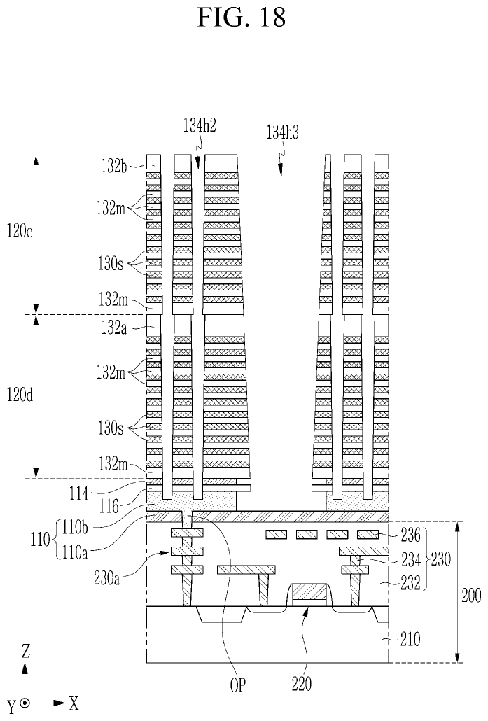

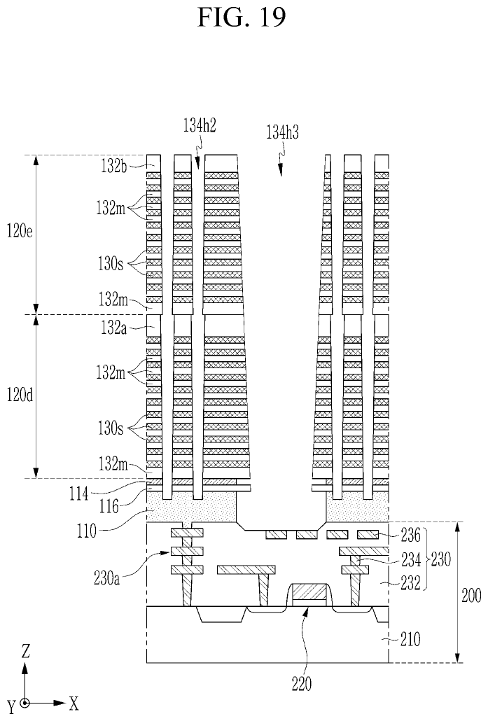

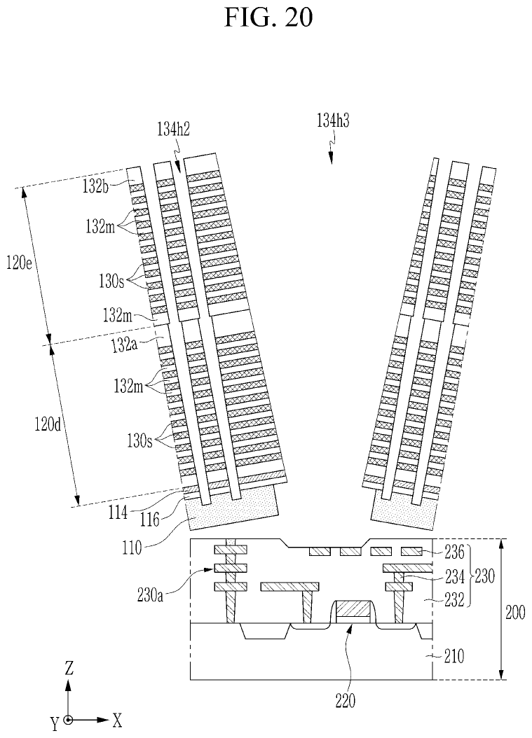

A semiconductor device according to an embodiment and a semiconductor device according to a reference example will now be described with reference to FIG. 17 to FIG. 20. FIG. 17 and FIG. 18 show some of a process for manufacturing a semiconductor device according to an embodiment, and FIG. 19 and FIG. 20 show some of a process for manufacturing a semiconductor device according to a reference embodiment. FIG. 17 to FIG. 20 show a case in which defects are generated when forming second channel holes passing through the second stacking structure body.

As shown in FIG. 17, in a process for manufacturing a semiconductor device according to an embodiment, a second stacking structure body 120e may be formed on the first stacking structure body 120d, where the channel sacrificial layer 134e, and the second stacking structure body 120e may be patterned to form a second channel hole 134h2. In various embodiments, an opening 134h3, which may be several times bigger than the second channel hole 134h2, may be generated because of impurities when the second stacking structure body 120e is patterned. The opening 134h3 may penetrate the first stacking structure body 120d in addition to the second stacking structure body 120e. Furthermore, the second horizontal conductive layer 114 and the horizontal insulation layer 116 may be penetrated by the opening 134h3. Hence, at least a portion of the second substrate 110 may be exposed. For example, the upper side of the second material layer 110b of the second substrate 110 may be exposed. In this instance, a thickness of the portion on which the second material layer 110b of the second substrate 110 is exposed may be partly reduced.

The channel sacrificial layer 134e may be exposed by the second channel hole 134h2. The second horizontal conductive layer 114, the horizontal insulation layer 116, and the second material layer 110b of the second substrate 110 may be exposed by the opening 134h3.

As shown in FIG. 18, the channel sacrificial layer 134e may be removed creating an open space in the first channel hole 134h1. In a process for removing the channel sacrificial layer 134e, other exposed layers made of the same material as the channel sacrificial layer 134e may be damaged. For example, the second horizontal conductive layer 114 and the second material layer 110b of the second substrate 110 may include the same material as the first channel sacrificial layer 134e1. In a process for etching the first channel sacrificial layer 134e1, the second horizontal conductive layer 114 and the second material layer 110b of the second substrate 110 exposed by the opening 134h3 may also be etched. Hence, the first material layer 110a disposed below the portion from the second material layer 110b of the second substrate 110 is removed may be exposed to the outside.

Regarding the semiconductor device according to an embodiment, the second substrate 110 includes a first material layer 110a and a second material layer 110b, where the first material layer 110a and the second material layer 110b may include polysilicon. The first material layer 110a and the second material layer 110b may also include different materials, where for example, the first material layer 110a may further include carbon, and the second material layer 110b may further include n-type impurities. By this, etching selecting ratios of the first material layer 110a and the second material layer 110b may be different.

Therefore, in a process for forming the second channel hole 134h2, defects may be generated by the opening 134h3 that exposes the second substrate 110, and when the second material layer 110b of the second substrate 110 is etched in a subsequent process, the first material layer 110a may not be etched but may remain. In a process for removing the channel sacrificial layer 134e, the first material layer 110a may not be damaged when at least part of the second material layer 110b of the second substrate 110 may be damaged, and at least part of the first material layer 110a is exposed. Therefore, the circuit region 200 disposed below the second substrate 110 may be protected. That is, the second wire portion 180 of the circuit region 200 may be prevented from being exposed to the outside and being damaged. In addition, the first stacking structure body 120d and the second stacking structure body 120e may be prevented from being separated from the circuit region 200.

As shown in FIG. 19, regarding the semiconductor device according to an example, the second substrate 110 may be a single layer, where for example, the second substrate 110 may include polysilicon to which n-type impurities are doped, and may not include a polysilicon layer including carbon. In a process for manufacturing a semiconductor device according to a reference example, the second channel hole 134h2 may be formed by patterning the second stacking structure body 120e. In this instance, the opening 134h3 may be generated as a defect to the first stacking structure body 120d and the second stacking structure body 120e. The second horizontal conductive layer 114, the horizontal insulation layer 116, and the second substrate 110 may be exposed by the opening 134h3.

As shown in FIG. 20, the channel sacrificial layer 134e may be removed, where in a process for removing the channel sacrificial layer 134e, the second horizontal conductive layer 114 and the second substrate 110 exposed by the opening 134h3 may be etched. The circuit region 200 disposed below the portion from which the second substrate 110 is removed may become damaged, where for example, the first insulation layer 232 disposed between the second substrate 110 and the wire layer 236 may be removed, and the wire layer 236 may be exposed to the outside.

In various embodiments, an oxidation process may be performed in a subsequent process, and some constituent elements of the semiconductor device, for example, the wire layer 236, which may be made of a metallic material, may be oxidized and its volume may expand. Accordingly, the second substrate 110 may peel off the circuit region 200, and the first stacking structure body 120d and the second stacking structure body 120e, as well as the second substrate 110, may be separated from the circuit region 200. As the subsequent process progresses, the area of the region where the first stacking structure body 120d and the second stacking structure body 120e are separated from the circuit region 200 may increase. For example, the separated area generated in an earlier stage may increase up to 5 times in later processes.

As described with reference to FIG. 17 to FIG. 20, in the process for manufacturing a semiconductor device according to an embodiment, when defects are generated in a predetermined region, it is possible to prevent the peripheral area from being affected by them.

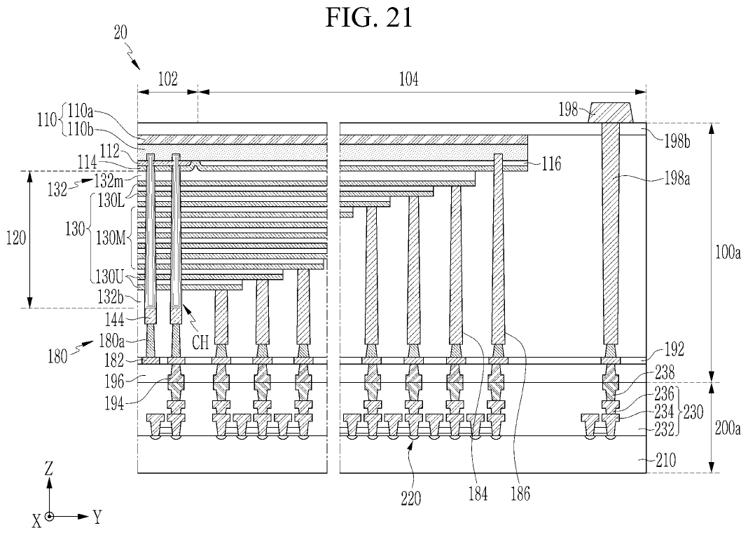

A semiconductor device according to an embodiment will now be described with reference to FIG. 21.

FIG. 21 shows a cross-sectional view of a semiconductor device according to an embodiment, where the embodiment shown in FIG. 21 mostly corresponds to the embodiment shown in FIG. 1 to FIG. 2B. The same constituent elements as the previously-described embodiment will use same reference numerals.

As shown in FIG. 21, the semiconductor device 20 according to an embodiment may have a chip to chip (C2C) structure generated by a wafer bonding method, where a lower chip including a circuit region 200a formed on the first substrate 210 may be manufactured, an upper chip including a cell region 100a formed on the second substrate 110 may be manufactured, and the semiconductor device 20 may be manufactured by bonding them.

In various embodiments, the circuit region 200a may include a first junction structure 238 on a side that faces the cell region 100a on the first substrate 210, the circuit element 220, and the first wire portion 230. The first junction structure 238 may be on and in electrical contact with a wire layer 236 in the first wire portion 230, and in electrical contact with a second junction structure 194 in an insulation layer 196.

The cell region 100a may include the second junction structure 194 on a side that faces the circuit region 200a on the second substrate 110, the gate stacking structure 120, the channel structure CH, and the second wire portion 180.

In various embodiments, the second substrate 110 may include a semiconductor material. The second substrate 110 may include a first material layer 110a and a second material layer 110b. A first material layer 110a may be disposed between the second material layer 110b and the horizontal conductive layers 112 and 114. The first material layer 110a and the second material layer 110b may include polysilicon. The first material layer 110a and the second material layer 110b may further include different materials. For example, the first material layer 110a may further include carbon, and the second material layer 110b may further include n-type impurities.

Regarding the gate stacking structure 120, the gate electrode 130 may include a lower gate electrode 130L, a memory cell gate electrode 130M, and an upper gate electrode 130U sequentially disposed on the second substrate 110. That is, as shown in FIG. 21, the gate stacking structure 120 may be sequentially stacked on a power portion of the second substrate 110 in the drawing, so the orientation of the gate stacking structure 120 shown in FIG. 1 to FIG. 2B may be reversed.

In various embodiments, the channel pad 144 and the second wire portion 180 disposed on the gate stacking structure 120 may be disposed near the circuit region 200a. The second junction structure 194 electrically connected to the second wire portion 180 may be provided on a side that faces the circuit region 200a. Regions exclusive of the second junction structure 194 may be covered by the insulation layer 196. The second wire portion 180 and the second junction structure 194 may be disposed to face the circuit region 200a in the cell region 100a.

In various embodiments, the second junction structure 194 of the cell region 100a and the first junction structure 238 of the circuit region 200a may be made of a conductive material, including, but not limited to, aluminum, copper, tungsten, or alloys thereof. For example, the first and second junction structures 238 and 194 may include copper, so the cell region 100a and the circuit region 200a may be physically and electrically connected (e.g., directly accessed and bonded) by a copper-to-copper junction.

FIG. 21 shows that the gate stacking structure 120 can be a single gate stacking structure, and as shown in FIG. 1, it may include a plurality of gate stacking structures. Descriptions of the configurations of the gate stacking structure 120 and the channel structure CH described with reference to FIG. 1 to FIG. 2B may be applied. Where for example, FIG. 21 shows that an electrical connection configuration of the channel structure CH to the horizontal conductive layers 112 and 114 and/or the second substrate 110 corresponds to what is described with reference to FIG. 1. The embodiment is not limited thereto, and the electrical connection configuration of the channel structure CH to the horizontal conductive layers 112 and 114 and/or the second substrate 110 may be modifiable in many ways.

In various embodiments, the semiconductor device 20 may include an input and output pad 198 and an input and output connecting wire 198a electrically connected thereto. The input and output connecting wire 198a may be electrically connected to part of the second junction structure 194. The input and output pad 198 may, for example, be disposed on an insulation layer 198b that may cover an external side of the second substrate 110. According to the embodiment, an additional input and output pad 198 that is electrically connected to the first input and output pad 198 may be provided in the circuit region 200a.

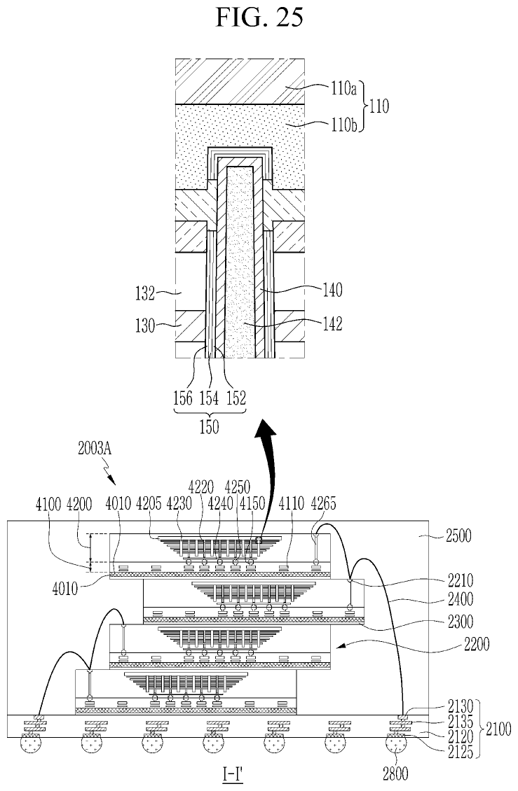

For example, the circuit region 200a and the cell region 100a may correspond to the first structure 1100F and the second structure 1100S of the semiconductor device 1100 included in the electronic system 1000 shown in FIG. 22. Alternatively, the circuit region 200a and the cell region 100a may correspond to the first structure 4100 and the second structure 4200 of the semiconductor chip 2200 shown in FIG. 25.

An electronic system including a semiconductor device according to an embodiment will now be described with reference to FIG. 22.

FIG. 22 shows an electronic system including a semiconductor device according to an embodiment.

As shown in FIG. 22, the electronic system 1000 may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive (SSD) device including one or multiple semiconductor devices 1100, a universal serial bus (USB), a computing system, a medical device, or a communication device.

In various embodiments, the semiconductor device 1100 may be a non-volatile memory device, for example, a NAND flash memory device described with reference to FIG. 1 to FIG. 2B, and FIG. 21. The semiconductor device 1100 may include a first structure 1100F and a second structure 1100S disposed on the first structure 1100F. In an embodiment, the first structure 1100F may be disposed near the second structure 1100S. The first structure 1100F may be a peripheral circuit structure including a decoder circuit 1110, a page buffer 1120, and a logic circuit 1130, where the decoder circuit 1110, a page buffer 1120, and a logic circuit 1130 can be electrically interconnected and electrically connected to the second structure 1100S. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL. The bit line BL may be electrically connected to the page buffer 1120, and first connecting wire 1115 may be electrically connected to the decoder circuit 1110.

Regarding the second structure 1100S, respective memory cell strings CSTR may include lower transistors LT1 and LT2 disposed near the common source line CSL, upper transistors UT1 and UT2 disposed near the bit line BL, and memory cell transistors MCT disposed between the lower transistors LT1 and LT2 and the upper transistors UT1 and UT2, where the lower transistors LT1 and LT2 and the upper transistors UT1 and UT2 may control signals to the memory cell transistors MCT. The number of the lower transistors LT1 and LT2 and the number of the upper transistors UT1 and UT2 may be modifiable in many ways depending on embodiments, for example, based on the number of memory cell transistors MCT.

In an embodiment, the lower transistors LT1 and LT2 may include a ground selecting transistor, and the upper transistors UT1 and UT2 may include a string selecting transistor. The first and second gate lower lines LL1 and LL2 may be gate electrodes of the lower transistors LT1 and LT2. The word line WL may be a gate electrode of the memory cell transistor MCT, and the gate upper lines UL1 and UL2 may be gate electrodes of the upper transistors UT1 and UT2.

The common source line CSL, the first and second gate lower lines LL1 and LL2, the word line WL, and the first and second gate upper lines UL1 and UL2 may be electrically connected to the decoder circuit 1110 through the first connecting wire 1115 extending to the second structure 1100S in the first structure 1100F. The bit line BL may be electrically connected to the page buffer 1120 through the second connecting wire 1125 extending to the second structure 1100S in the first structure 1100F.

Regarding the first structure 1100F, the decoder circuit 1110 and the page buffer 1120 may control at least one of the memory cell transistors MCT. The decoder circuit 1110 and the page buffer 1120 may be controlled by the logic circuit 1130. The semiconductor device 1100 may communicate with the controller 1200 through an input and output pad 1101 electrically connected to the logic circuit 1130 by input and output connecting wire 1135. The input and output pad 1101 may be electrically connected to the logic circuit 1130 through an input and output connecting wire 1135 extending through the second structure 1100S to the first structure 1100F.

In various embodiments, the controller 1200 may include a processor 1210, a NAND controller 1220, and a host interface 1230. Depending on embodiments, the electronic system 1000 may include semiconductor devices 1100, and the controller 1200 may control the semiconductor devices 1100.

In various embodiments, the processor 1210 may control general operation of the electronic system 1000 including the controller 1200. The processor 1210 may be operable according to predetermined firmware, and may control the NAND controller 1220 to access the semiconductor device 1100. The NAND controller 1220 may include a NAND interface 1221 for processing communication with the semiconductor device 1100. Control instructions for controlling the semiconductor device 1100, data to be written to the memory cell transistor MCT of the semiconductor device 1100, and data to be read from the memory cell transistor MCT of the semiconductor device 1100 may be transmitted through the NAND interface 1221. The host interface 1230 may provide a communication function between the electronic system 1000 and an external host. When receiving the control instruction from the external host through the host interface 1230, the processor 1210 may control the semiconductor device 1100 in response to the control instruction.

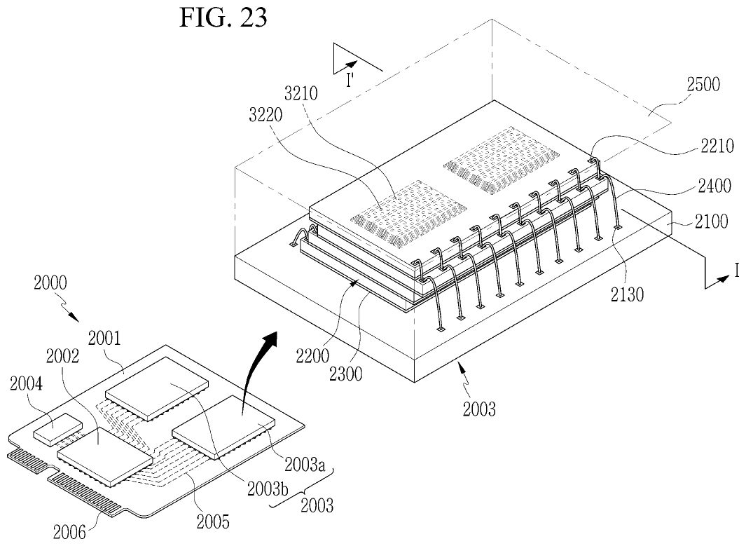

FIG. 23 shows a perspective view of an electronic system including a semiconductor device according to an embodiment.

As shown in FIG. 23, the electronic system 2000 may include a main substrate 2001, a controller 2002 installed on the main substrate 2001, at least one semiconductor package 2003, and a DRAM 2004. The semiconductor package 2003 and the DRAM 2004 may be connected to the controller 2002 by a wire pattern 2005 formed on the main substrate 2001.

In various embodiments, the main substrate 2001 may include a connector 2006 including pins combined to the external host, where the number and the disposition of the pins of the connector 2006 are variable based on a configuration of a communication interface between the electronic system 2000 and an external host. In an embodiment, the electronic system 2000 may communicate with the external host according to one of the interfaces including a universal serial bus (USB), a peripheral component interconnect express (PCI-Express), a serial advanced technology attachment (SATA), and a universal flash storage (UFS) M-Phy. In an embodiment, the electronic system 2000 may be operated by a power voltage supplied by the external host through the connector 2006. The electronic system 2000 may further include a power management integrated circuit (PMIC) for providing the power voltage supplied by the external host to the controller 2002 and the semiconductor package 2003.

In various embodiments, the controller 2002 may write data to the semiconductor package 2003, may read the data from the semiconductor package 2003, and may increase operation rates of the electronic system 2000.

The DRAM 2004 may be a buffer memory for reducing rate differences between the semiconductor package 2003 that is a data storage space and the external host. The DRAM 2004 included in the electronic system 2000 may be operated as a cache memory, and may provide a space for temporarily storing data when controlling the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced from each other. The first and second semiconductor packages 2003a and 2003b may respectively include a plurality of semiconductor chips 2200. The first and second semiconductor packages 2003a and 2003b may include a package substrate 2100, semiconductor chips 2200 disposed on the package substrate 2100, an adhesive layer 2300 disposed on bottom surfaces of the respective semiconductor chips 2200, a connection structure 2400 for electrically connecting the semiconductor chip 2200 and the package substrate 2100, and a molding layer 2500 for covering the semiconductor chip 2200 and the connection structure 2400 on the package substrate 2100. The adhesive layer 2300 can affix semiconductor chips 2200 to each other and to the package substrate 2100.

In various embodiments, the package substrate 2100 may be a flexible printed circuit FPC including a package upper pad 2130 for electrical connection. The respective semiconductor chips 2200 may include an input and output pad 2210. The input and output pad 2210 may correspond to the input and output pad 1101 of FIG. 22. The respective semiconductor chips 2200 may include a gate stacking structure 3210 and a channel structure 3220. The respective semiconductor chips 2200 may include the semiconductor device described with reference to FIG. 1 to FIG. 2B and FIG. 21.

In an embodiment, the connection structure 2400 may be a bonding wire for electrically connecting the input and output pad 2210 and the package upper pad 2130. Therefore, regarding the first and second semiconductor packages 2003a and 2003b, the semiconductor chips 2200 may be electrically connected to each other by a wire bonding method, and may be electrically connected to the package upper pad 2130 of the package substrate 2100. Depending on embodiments, regarding the first and second semiconductor packages 2003a and 2003b, the semiconductor chips 2200 may be electrically connected to each other not by the connection structure 2400 according to a wire bonding method but by a connection structure including a through silicon via TSV.

In an embodiment, the controller 2002 and the semiconductor chips 2200 may be included in one package. For example, the controller 2002 and the semiconductor chip 2200 may be installed on an interposer substrate that is different from the main substrate 2001, and the controller 2002 may be connected to the semiconductor chips 2200 by a wire formed on the interposer substrate.

FIG. 24 and FIG. 25 show cross-sectional views of a semiconductor package according to an embodiment. FIG. 24 and FIG. 25 respectively show an embodiment of the semiconductor package 2003 of FIG. 23, and conceptually show an incised region of the semiconductor package 2003 of FIG. 23 along a cutting line I-I′.

Referring to FIG. 24, regarding the semiconductor package 2003, the package substrate 2100 may be a flexible printed circuit FPC. The package substrate 2100 may include a package substrate body portion 2120, a package upper pad 2130 disposed on an upper side of the package substrate body portion 2120, a lower pad 2125 disposed on a lower side of the package substrate body portion 2120 or exposed through the lower side, and an internal wire 2135 for electrically connecting the upper pad 2130 and the lower pad 2125 inside the package substrate body portion 2120. The upper pad 2130 may be electrically connected to the connection structure 2400. The lower pad 2125 may be connected to the wire pattern 2005 of the main substrate 2001 of the electronic system 2000 through a conductive connector 2800 as shown in FIG. 23.

In various embodiments, the semiconductor chips 2200 may include a semiconductor substrate 3010 and a first structure 3100 and a second structure 3200 sequentially stacked on the semiconductor substrate 3010. The first structure 3100 may include a peripheral circuit region including a peripheral wire 3110. The second structure 3200 may include a common source line 3205, a gate stacking structure 3210 disposed on the common source line 3205, a channel structure 3220 and a separation structure 3230 passing through the gate stacking structure 3210, a bit line 3240 electrically connected to the channel structure 3220, and a gate connecting wire electrically connected to the word line WL of FIG. 22 of the gate stacking structure 3210.

Regarding the semiconductor chips 2200 or the semiconductor device according to an embodiment, the second substrate 110 includes the first material layer 110a and the second material layer 110b with different etching selectivity, thereby preventing generation of defects during the process and increasing reliability and productivity of the semiconductor device.

The respective semiconductor chips 2200 may include a penetrating wire 3245 electrically connected to the peripheral wire 3110 of the first structure 3100 and extending into the second structure 3200. The penetrating wire 3245 may pass through the gate stacking structure 3210, and may be further disposed on the outside of the gate stacking structure 3210. The respective semiconductor chips 2200 may further include an input and output connecting wire 3265 electrically connected to the peripheral wire 3110 of the first structure 3100 and extending into the second structure 3200 and an input and output pad 2210 electrically connected to the input and output connecting wire 3265.

In an embodiment, the semiconductor chips 2200 may be electrically connected to each other by a connection structure 2400 in a bonding wire form in the semiconductor package 2003. For another example, the semiconductor chips 2200 or portions configuring them may be electrically connected to each other by a connection structure including a through silicon via TSV.

Referring to FIG. 25, regarding the semiconductor package 2003A, the respective semiconductor chips 2200 may include a semiconductor substrate 4010, a first structure 4100 disposed on the semiconductor substrate 4010, and a second structure 4200 bonded to the first structure 4100 on the first structure 4100 by a wafer bonding method.

In various embodiments, the first structure 4100 may include a peripheral circuit region including a peripheral wire 4110 and a first junction structure 4150. The second structure 4200 may include a common source line 4205, a gate stacking structure 4210 disposed between the common source line 4205 and the first structure 4100, a channel structure 4220 and a separation structure 4230 passing through the gate stacking structure 4210, and a second junction structure 4250 electrically connected to the word line WL of FIG. 22 of the channel structure 4220 and the gate stacking structure 4210. For example, the second junction structure 4250 may be electrically connected to the channel structure 4220 and the word line WL through the bit line 4240 electrically connected to the channel structure 4220 and the gate connecting wire electrically connected to the word line WL. The first junction structure 4150 of the first structure 4100 and the second junction structure 4250 of the second structure 4200 may contact each other and may be bonded to each other. The bonded portion of the first junction structure 4150 and the second junction structure 4250 may be made of, for example, copper (Cu).

Regarding the semiconductor chips 2200 and/or the semiconductor device according to an embodiment, the second substrate 110 includes the first material layer 110a and the second material layer 110b with different values of etching selectivity, thereby preventing the generation of defects during the process and increasing reliability and productivity of the semiconductor device.

The respective semiconductor chips 2200 may further include an input and output pad 2210 and an input and output connecting wire 4265 disposed on a lower portion of the input and output pad 2210. The input and output connecting wire 4265 may be electrically connected to a portion of the second junction structure 4250.

In an embodiment, the semiconductor chips 2200 may be electrically connected to each other by the connection structure 2400 in a bonding wire shape on the semiconductor package 2003, where for example, the semiconductor chips 2200 or portions of the same may be electrically connected to each other by a connection structure including through silicon vias.

While this disclosure has been described in connection with various embodiments, it is to be understood that the disclosure is not limited to the disclosed embodiments, but is intended to cover various modifications and equivalent arrangements included within the spirit and scope of the appended claims.

### DESCRIPTION OF SYMBOLS

110: second substrate
110a: first material layer
110b: second material layer
120a: first gate stacking structure
120b: second gate stacking structure
200: circuit region
210: first substrate
230: first wire portion
230a: floating electrode
CH: channel structure

What is claimed is:

1. A semiconductor device comprising:
a first substrate;
a wire portion on the first substrate;
a second substrate on the wire portion;
a first gate stacking structure on the second substrate;
a second gate stacking structure on the first gate stacking structure; and
a channel structure passing through the first gate stacking structure and the second gate stacking structure and connected to the second substrate,
wherein the second substrate includes a first material layer and a second material layer on the first material layer,
the first material layer includes polysilicon including a first material,
the second material layer includes polysilicon including a second material different from the first material, and
an insulation layer is disposed between the wire layer and the second substrate.

2. The semiconductor device of claim 1, wherein
the first material layer and the second material layer have different values of etching selectivity.

3. The semiconductor device of claim 1, wherein
the first material layer includes polysilicon doped with carbon, and
the second material layer includes n-doped polysilicon.

4. The semiconductor device of claim 1, wherein
the wire portion includes a floating electrode disposed between the first substrate and the second substrate, and
the second substrate is electrically connected to the floating electrode.

5. The semiconductor device of claim 4, wherein
the floating electrode is electrically connected to the first substrate.

6. The semiconductor device of claim 4, wherein
the floating electrode electrically floats.

7. The semiconductor device of claim 4, wherein
the wire portion further includes
a plurality of wire layers, and
a contact via connecting adjacent pairs of the plurality of wire layers,
the insulation layer covers the plurality of wire layers and the floating electrode, and
the floating electrode includes a plurality of layers disposed on a same layer as the plurality of wire layers and the contact via.

8. The semiconductor device of claim 7, wherein
a second material layer of the second substrate is electrically connected to the floating electrode through an opening in the insulation layer and the first material layer.

9. The semiconductor device of claim 8, wherein
a first material layer of the second substrate is not directly connected electrically to the floating electrode.

10. The semiconductor device of claim 1, wherein
the channel structure includes
a channel layer, and
a gate dielectric layer disposed between the channel layer and the first and second gate stacking structures.

11. The semiconductor device of claim 10, further comprising
a horizontal conductive layer disposed on the second substrate,
wherein the horizontal conductive layer electrically connects the second substrate and the channel layer.

12. The semiconductor device of claim 11, wherein
the channel structure further includes a core insulation layer surrounded by the channel layer, and
the gate dielectric layer includes a tunneling layer, a charge storage layer, and a blocking layer sequentially stacked on the channel layer.

13. A semiconductor device comprising:
a wire portion on a first substrate, where the wire portion includes a wire layer and an insulation layer covering the wire layer;
a second substrate on the wire portion;
a gate stacking structure on the second substrate; and
a channel structure passing through the gate stacking structure and electrically connected to the second substrate,
wherein the second substrate includes a first material region and a second material region on the first material region,
the first material region includes polysilicon doped with carbon,
the second material region includes n-doped polysilicon, and
the insulation layer is between the wire layer and the second substrate, and a first side of the first material region contacts the insulation layer.

14. The semiconductor device of claim 13, wherein
the first material region and the second material region have different values of etching selectivity.

15. The semiconductor device of claim 13, wherein
the wire portion further includes
a plurality of wire layers,
a contact via for electrically connecting the plurality of wire layers, and
a floating electrode including a plurality of layers on a same layer as the plurality of wire layers and the contact via,
the insulation layer covers the plurality of wire layers and the floating electrode, and
the second substrate is electrically connected to the floating electrode.

16. The semiconductor device of claim 15, wherein
a second material region of the second substrate is electrically connected to the floating electrode through an opening in the insulation layer and the first material region.

17. The semiconductor device of claim 15, wherein
the floating electrode is electrically connected to the first substrate.

18. An electronic system comprising:
a main substrate;
a semiconductor device disposed on the main substrate; and
a controller electrically connected to the semiconductor device on the main substrate,
wherein the semiconductor device includes a circuit region and a cell region disposed in the circuit region,
the circuit region includes
a first substrate,
a wire layer disposed on the first substrate, and
an insulation layer disposed on the wire layer,
the cell region includes
a second substrate,
a first gate stacking structure including an interlayer insulating layer and a gate electrode alternately stacked on the second substrate,
a second gate stacking structure including an interlayer insulating layer and a gate electrode alternately stacked on the first gate stacking structure, and
a channel structure passing through the first gate stacking structure and the second gate stacking structure and connected to the second substrate,
the substrate includes a first material layer and a second material layer disposed on the first material layer,
the first material layer includes polysilicon including a first material,
the second material layer includes polysilicon including a second material that is different from the first material, and
the insulation layer is disposed between the wire layer and the second substrate, and a first side of the first material layer contacts the insulation layer.

19. The electronic system of claim 18, wherein
the first material layer includes polysilicon doped with carbon, and
the second material layer includes n-doped polysilicon.

20. The electronic system of claim 19, wherein
the wire portion includes a floating electrode disposed between the first substrate and the second substrate, and
a second material layer of the second substrate is electrically connected to the floating electrode.
